(19) United States
(12) Patent Application Publication
(10) Pub. No.: US 2026/0293557 A1
(43) Pub. Date: Sep. 24, 2026

(54) COMPOSITION, METHOD OF TREATING METAL-CONTAINING FILM AND METHOD OF MANUFACTURING ELECTRONIC DEVICE

(71) Applicant: Samsung Electronics Co., Ltd., Suwon-si (KR)

(72) Inventors: Byungjoon KANG, Suwon-si (KR); Jungah KIM, Suwon-si (KR); Insun PARK, Suwon-si (KR); Jeongil PARK, Suwon-si (KR); Sangwon BAE, Suwon-si (KR); Minjae SUNG, Suwon-si (KR); Kum Hee LEE, Suwon-si (KR); Kyuyoung HWANG, Suwon-si (KR); Youngji HWANG, Suwon-si (KR)

(73) Assignee: Samsung Electronics Co., Ltd., Suwon-si (KR)

(21) Appl. No.: 19/559,409

(22) Filed: Mar. 6, 2026

(30) Foreign Application Priority Data
Mar. 13, 2025 (KR) 10-2025-0032941

(51) Int. Cl. H10P 50/66; C09K 13/06; H10D 64/01

(52) U.S. Cl. CPC H10P 50/667; C09K 13/06; H10D 64/027

(57) ABSTRACT

Provided are a composition, a method of treating a metal-containing film by using the same, and a method of manufacturing an electronic device by using the same, the composition including an oxidizing agent, phosphoric acid, an organic acid, and an etching controller, wherein the oxidizing agent includes hydrogen peroxide and an iodine-containing compound, the etching controller includes a nitrogen-containing compound, and the composition has a pH of less than 1.

### CROSS-REFERENCE TO RELATED APPLICATION

This application is based on and claims priority under 35 USC § 119 to Korean Patent Application No. 10-2025-0032941, filed on Mar. 13, 2025, in the Korean Intellectual Property Office, the disclosure of which is incorporated by reference herein in its entirety.

### BACKGROUND

### 1. Field

The disclosure relates to a composition, a method of treating a metal-containing film by using the composition, and a method of manufacturing an electronic device by using the same.

### 2. Description of the Related Art

In order to meet consumer demands for excellent performance and low cost, improvements in the integration density and reliability of various electronic devices (such as semiconductor devices) are being explored. For example, compositions and methods for manufacturing process of such semiconductor devices are being explored to improve the integration density and/or reliability. For example, improvements to the various treatment processes such as etching, cleaning, and polishing, which may be performed on films (for example, metal-containing films) comprising the electronic device, are being explored. However, as the integration density of semiconductor devices increases, damage to the components of the semiconductor device during the manufacturing process may have a greater impact on the reliability and electrical characteristics of the device. In particular. Accordingly, there is a continuing need for compositions having appropriate etch rates, or the like, to effectively carry out metal-containing film treatment processes.

### SUMMARY

Provided is a composition capable of effectively controlling the etch rate for various metal-containing films, a method of treating a metal-containing film using the composition, and a method of manufacturing an electronic device using the composition.

Additional aspects will be set forth in part in the description which follows and, in part, will be apparent from the description, or may be learned by practice of the presented embodiments of the disclosure.

According to an aspect of the disclosure, a composition includes an oxidizing agent, phosphoric acid, an organic acid and an etching controller, wherein the oxidizing agent includes hydrogen peroxide and an iodine-containing compound, the etching controller includes a nitrogen-containing compound, and the composition has a pH of less than 1.

According to an aspect of the disclosure, a method of treating a metal-containing film includes preparing a substrate including the metal-containing film, the metal-containing film including a first region and a second region, the first region including a material different from a material of the second region; and contacting the metal-containing film with a composition; wherein the first region and the second region independently comprise titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or a combination thereof, the composition comprises an oxidizing agent, phosphoric acid, an organic acid, and an etching controller, the oxidizing agent comprises hydrogen peroxide and an iodine-containing compound, the etching controller comprises a nitrogen-containing compound, and the composition has a pH of less than 1.

According to an aspect of the disclosure, a method of manufacturing an electronic device including a transistor the transistor comprising a channel, a source and a drain spaced apart from each other and electrically connected to the channel, a gate electrode, and a gate insulating film between the gate electrode and the channel, the method comprising: providing a barrier layer, the barrier layer comprising a metal nitride, a metal oxynitride, or a combination thereof; providing a conductive layer including a conductive metal; and forming the gate electrode by etching a portion of the barrier layer and a portion of the conductive layer using a composition, the composition comprising an oxidizing agent, phosphoric acid, an organic acid, and an etching controller, wherein the oxidizing agent comprises hydrogen peroxide and an iodine-containing compound, the etching controller comprises a nitrogen-containing compound, and the composition has a pH of less than 1.

### BRIEF DESCRIPTION OF THE DRAWINGS

The above and other aspects, features, and advantages of certain embodiments of the disclosure will be more apparent from the following description taken in conjunction with the accompanying drawings, in which:

FIGS. 1A and 2 are schematic views briefly illustrating at least one example embodiment of a method of treating a metal-containing film;

FIG. 1B is a schematic view showing the surface of a metal-containing film (20A) of FIG. 1A that may be brought into contact with a composition (30);

FIGS. 3 and 4 are schematic views briefly illustrating some example embodiments of a method of treating a metal-containing film;

FIG. 5 is a schematic plan view of an electronic device according to at least one example embodiment;

FIG. 6A is a perspective view of at least one example embodiment of the electronic device illustrated in FIG. 5;

FIG. 6B is a perspective view of at least one example embodiment of the electronic device shown in FIG. 5;

FIGS. 7 to 9 are schematic views briefly illustrating parts of a process of manufacturing the transistor structure shown in FIG. 6A;

FIG. 10 is a process flowchart of at least one example embodiment of a method of manufacturing an electronic device;

FIG. 11A is a photograph of a molybdenum film surface obtained after immersion in the composition of Example 1;

FIG. 11B is a photograph of a molybdenum film surface obtained after immersion in the composition of Comparative Example C1; and

FIG. 12 is a photograph of a molybdenum film surface obtained after immersion in the composition of Example 11.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, expressions such as “at least one of A, B, and C” or “at least one selected from the group consisting of A, B, and C” may be interpreted as only A, only B, only C, or a combination of two or more of A, B, and C, e.g., A-B-C, A-B, B-C, and/or A-C.

It will also be understood that spatially relative terms, such as “above”, “top”, etc., are intended to encompass different orientations of the device in use or operation in addition to the orientation depicted in the figures, and that the device may be otherwise oriented (rotated 90 degrees or at other orientations) and the spatially relative terms used herein interpreted accordingly; and the term “upper portion” or “on” may also include “to be present above, below, in the left and right sides on a non-contact basis” as well as “to be on the top, bottom, left, and right portions in directly contact with”.

When the terms such as “about” or “substantially” are used in relation to numerical values, the relevant numerical value may be construed as including a manufacturing or operation deviation (e.g., +10%) of the stated numerical value. In addition, when the expressions such as “generally” and “substantially” are used in relation to a geometric shape, the geometric precision may not be required, and the intention is that the degree of tolerance regarding the shape is within the scope of embodiments of the disclosure. Moreover, regardless of whether a numerical value of a shape is limited by using “about” or “substantially”, such numerical value or shape should be understood as including a manufacturing or operation deviation (e.g., +10%) of the stated numerical value.

While such terms as “first,” “second,” etc., may be used to describe various components, such components must not be limited to the above terms. The above terms are used only to distinguish one component from another.

The use of any and all examples, and/or exemplary language provided herein, is intended merely to better illuminate technical ideas and does not pose a limitation on the scope of embodiments unless otherwise claimed.

### Metal-Containing Film

The metal-containing film may include an alkali metal (for example, sodium (Na), potassium (K), rubidium (Rb), cesium (Cs), and/or the like), an alkaline earth metal (for example, beryllium (Be), magnesium (Mg), calcium (Ca), strontium (Sr), barium (Ba), and/or the like), a lanthanide metal (for example, lanthanum (La), europium (Eu), terbium (Tb), ytterbium (Yb), and/or the like), a transition metal (for example, scandium (Sc), yttrium (Y), titanium (Ti), zirconium (Zr), hafnium (Hf), vanadium (V), niobium (Nb), tantalum (Ta), chromium (Cr), molybdenum (Mo), tungsten (W), manganese (Mn), iron (Fe), ruthenium (Ru), osmium (Os), cobalt (Co), rhodium (Rh), nickel (Ni), copper (Cu), silver (Ag), zinc (Zn), and/or the like), post-transition metals (for example, aluminum (Al), gallium (Ga), indium (In), thallium (Tl), tin (Sn), bismuth (Bi), and/or the like), a combination thereof, and/or the like.

According to at least one example embodiment, the metal-containing film may include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), and/or a combination thereof.

According to at least one example embodiment, the metal-containing film may include two or more different types of metals.

According to at least one example embodiment, the metal-containing film may include titanium.

According to at least one example embodiment, the metal-containing film may i) include titanium (Ti), and ii) optionally further include, in addition to titanium, indium (In), aluminum (Al), lanthanum (La), scandium (Sc), gallium (Ga), tungsten (W), molybdenum (Mo), ruthenium (Ru), zinc (Zn), hafnium (Hf), silicon (Si), and/or a combination thereof.

The metal-containing film may be and/or include a metal film, a metal nitride film, a metal oxide film, a metal oxynitride film, and/or a combination thereof.

For example, according to at least one example embodiment, the metal-containing film may include a metal, a metal nitride, a metal oxide, a metal oxynitride, and/or a combination thereof, and each of the metal, the metal of the metal nitride, the metal of the metal oxide, and the metal of the metal oxynitride may include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), and/or a combination thereof.

According to at least one example embodiment, the metal-containing film may include a metal nitride, a metal oxynitride, and/or a combination thereof as described above (for example, a titanium nitride, a titanium oxynitride, and/or a combination thereof, and/or the like).

According to at least one example embodiment, the metal-containing film may include a metal as described above (for example, a conductive metal such as tungsten, molybdenum, and ruthenium).

According to at least one example embodiment, the metal-containing film may include i) a metal nitride, a metal oxynitride, and/or a combination thereof as described above (for example, a titanium nitride, a titanium oxynitride, and/or a combination thereof, or the like) and ii) a conductive metal (for example, a conductive metal such as tungsten, molybdenum, and ruthenium).

According to at least one example embodiment, the metal-containing film may include a titanium nitride, a titanium oxynitride, and/or a combination thereof, and may further include tungsten, molybdenum, ruthenium, and/or a combination thereof, in addition to the titanium nitride, the titanium oxynitride, and/or a combination thereof. Each of the titanium nitride and titanium oxynitride may optionally further include indium, aluminum, lanthanum, scandium, gallium, silicon, and/or a combination thereof.

According to at least one example embodiment, the metal-containing film may include a titanium nitride, a titanium nitride further including aluminum (for example, TiAIN), a titanium nitride further including lanthanum, a titanium nitride further including silicon (for example, TiSiN), or the like.

The metal-containing film may be a single-layer structure including one or more types of materials or a multi-layer structure including different materials. The plurality of the films included in the multilayer structure may be vertically stacked or horizontally arranged with respect to the substrate. The single-layer structure and the multi-layer structure may have various three-dimensional patterns (for example, via holes, trenches, or the like).

According to at least one example embodiment, the metal-containing film includes a first region and a second region, wherein the first region and the second region independently include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), and/or a combination thereof, and the material included in the first region may be different from the material included in the second region.

According to at least one example embodiment, the first region may include titanium.

According to at least one example embodiment, the first region may i) include titanium (Ti), and ii) in addition to titanium, optionally further include indium (In), aluminum (Al), lanthanum (La), scandium (Sc), gallium (Ga), tungsten (W), molybdenum (Mo), ruthenium (Ru), zinc (Zn), hafnium (Hf), silicon (Si), and/or a combination thereof.

According to at least one example embodiment, the second region may include tungsten (W), molybdenum (Mo), ruthenium (Ru), and/or a combination thereof.

According to at least one example embodiment, the first region may include titanium (Ti), indium (In), aluminum (Al), lanthanum (La), scandium (Sc), gallium (Ga), and/or a combination thereof, and the second region may include tungsten (W), molybdenum (Mo), ruthenium (Ru), and/or a combination thereof.

According to at least one example embodiment, the first region may include a metal nitride, a metal oxynitride, and/or a combination thereof, and the second region may include a conductive metal.

For example, the first region may have i) a single-layer structure of a metal nitride film, ii) a single-layer structure of a metal oxynitride film, or iii) a double-layer structure of a metal nitride film and a metal oxynitride film.

According to at least one example embodiment, the first region may include a titanium nitride, a titanium oxynitride, and/or a combination thereof, wherein each of the titanium nitride and the titanium oxynitride may optionally further include indium (In), aluminum (Al), lanthanum (La), scandium (Sc), gallium (Ga), silicon (Si), and/or a combination thereof.

According to at least one example embodiment, the first region may include a titanium nitride, a titanium nitride further including aluminum (for example, TiAIN), a titanium nitride further including lanthanum, a titanium nitride further including silicon (for example, TiSiN), and/or the like.

As used herein, the etching of any film may refer to that at least a portion of the material constituting the film is removed.

### Composition

The composition may include an oxidizing agent, phosphoric acid, an organic acid, and an etching controller.

The composition may be used in various treatment processes for the metal-containing film described herein, such as etching, cleaning, and polishing processes.

The composition may further include a polar solvent (e.g., water).

According to at least one example embodiment, the composition may not include a fluorine-containing compound. Although not intended to be limited by any particular theory, when the composition includes a fluorine-containing compound, during treatment processes for the metal-containing film using the same, adjacent materials, such as various oxides or the like, disposed adjacent to the metal-containing film as described below may be damaged, resulting in a deterioration in the performance of electronic devices and/or semiconductor devices.

### Oxidizing Agent

The oxidizing agent serves to etch away at least part of the metal-containing film, and may include hydrogen peroxide and an iodine-containing compound.

According to at least one example embodiment, the iodine-containing compound may include iodine, periodic acid (H₅IO₆ and/or HIO₄), iodic acid (HIO₃), and/or a combination thereof.

According to at least one example embodiment, the oxidizing agent may include hydrogen peroxide and iodic acid.

According to at least one example embodiment, the oxidizing agent may include hydrogen peroxide and periodic acid.

According to at least one example embodiment, the composition may not include a fluorine-containing compound (for example, HF, NH₄F, or the like) as an oxidizing agent. Although not intended to be limited by any particular theory, when the composition includes a fluorine-containing compound as an oxidizing agent, during treatment processes for the metal-containing film using the same, adjacent materials, such as various oxides or the like, disposed adjacent to the metal-containing film as described below may be damaged, resulting in a deterioration in the performance of electronic devices and/or semiconductor devices.

The content (by weight) of the oxidizing agent may be, for example, based on 100 wt % of the composition, about 0.001 wt % to about 10 wt %, about 0.001 wt % to about 7 wt %, about 0.001 wt % to about 5 wt %, about 0.001 wt % to about 3 wt %, about 0.001 wt % to about 1 wt %, about 0.001 wt % to about 0.7 wt %, about 0.005 wt % to about 10 wt %, about 0.005 wt % to about 7 wt %, about 0.005 wt % to about 5 wt %, about 0.005 wt % to about 3 wt %, about 0.005 wt % to about 1 wt %, about 0.005 wt % to about 0.7 wt %, about 0.01 wt % to about 10 wt %, about 0.01 wt % to about 7 wt %, about 0.01 wt % to about 5 wt %, about 0.01 wt % to about 3 wt %, about 0.01 wt % to about 1 wt %, about 0.01 wt % to about 0.7 wt %, about 0.05 wt % to about 10 wt %, about 0.05 wt % to about 7 wt %, about 0.05 wt % to about 5 wt %, about 0.05 wt % to about 3 wt %, about 0.05 wt % to about 1 wt %, about 0.05 wt % to about 0.7 wt %, about 0.1 wt % to about 10 wt %, about 0.1 wt % to about 7 wt %, about 0.1 wt % to about 5 wt %, about 0.1 wt % to about 3 wt %, about 0.1 wt % to about 1 wt %, about 0.1 wt % to about 0.7 wt %, about 0.3 wt % to about 10 wt %, about 0.3 wt % to about 7 wt %, about 0.3 wt % to about 5 wt %, about 0.3 wt % to about 3 wt %, about 0.3 wt % to about 1 wt %, and/or about 0.3 wt % to about 0.7 wt %.

The weight ratio of the iodine-containing compound to the hydrogen peroxide may be about 1:10 to about 1:100, about 1:10 to about 1:50, and/or about 1:15 to about 1:30.

The content (by weight) of the hydrogen peroxide may be, for example, based on 100 wt % of the composition, about 0.01 wt % to about 10 wt %, about 0.01 wt % to about 7 wt %, about 0.01 wt % to about 5 wt %, about 0.01 wt % to about 3 wt %, about 0.01 wt % to about 1 wt %, about 0.01 wt % to about 0.7 wt %, about 0.05 wt % to about 10 wt %, about 0.05 wt % to about 7 wt %, about 0.05 wt % to about 5 wt %, about 0.05 wt % to about 3 wt %, about 0.05 wt % to about 1 wt %, about 0.05 wt % to about 0.7 wt %, about 0.1 wt % to about 10 wt %, about 0.1 wt % to about 7 wt %, about 0.1 wt % to about 5 wt %, about 0.1 wt % to about 3 wt %, about 0.1 wt % to about 1 wt %, about 0.1 wt % to about 0.7 wt %, about 0.3 wt % to about 10 wt %, about 0.3 wt % to about 7 wt %, about 0.3 wt % to about 5 wt %, about 0.3 wt % to about 3 wt %, about 0.3 wt % to about 1 wt %, and/or about 0.3 wt % to about 0.7 wt %.

The content (by weight) of the iodine-containing compound may be, for example, based on 100 wt % of the composition, about 0.001 wt % to about 5 wt %, about 0.001 wt % to about 3 wt %, about 0.001 wt % to about 1 wt %, about 0.001 wt % to about 0.5 wt %, about 0.005 wt % to about 5 wt %, about 0.005 wt % to about 3 wt %, about 0.005 wt % to about 1 wt %, about 0.005 wt % to about 0.5 wt %, about 0.01 wt % to about 5 wt %, about 0.01 wt % to about 3 wt %, about 0.01 wt % to about 1 wt %, and/or about 0.01 wt % to about 0.5 wt %.

### Phosphoric Acid

The phosphoric acid, together with the oxidizing agent, may serve to etch at least a portion of the metal-containing film.

According to at least one example embodiment, the composition may not include sulfuric acid, hydrochloric acid, or nitric acid. Although not intended to be limited by any particular theory, when sulfuric acid, hydrochloric acid, or nitric acid is used in combination with the above-described oxidizing agent, the stability of the composition may deteriorate, making it unsuitable for use in metal-containing film treatment processes.

The content (weight) of the phosphoric acid may be, for example, based on 100 wt % of the composition, about 10 wt % to about 85 wt %, about 15 wt % to about 85 wt %, about 20 wt % to about 85 wt %, about 25 wt % to about 85 wt %, about 30 wt % to about 85 wt %, about 35 wt % to about 85 wt %, about 40 wt % to about 85 wt %, about 45 wt % to about 85 wt %, about 50 wt % to about 85 wt %, about 55 wt % to about 85 wt %, about 10 wt % to about 80 wt %, about 15 wt % to about 80 wt %, about 20 wt % to about 80 wt %, about 25 wt % to about 80 wt %, about 30 wt % to about 80 wt %, about 35 wt % to about 80 wt %, about 40 wt % to about 80 wt %, about 45 wt % to about 80 wt %, about 50 wt % to about 80 wt %, about 55 wt % to about 80 wt %, about 10 wt % to about 75 wt %, about 15 wt % to about 75 wt %, about 20 wt % to about 75 wt %, about 25 wt % to about 75 wt %, about 30 wt % to about 75 wt %, about 35 wt % to about 75 wt %, about 40 wt % to about 75 wt %, about 45 wt % to about 75 wt %, about 50 wt % to about 75 wt %, about 55 wt % to about 75 wt %, about 10 wt % to about 70 wt %, about 15 wt % to about 70 wt %, about 20 wt % to about 70 wt %, about 25 wt % to about 70 wt %, about 30 wt % to about 70 wt %, about 35 wt % to about 70 wt %, about 40 wt % to about 70 wt %, about 45 wt % to about 70 wt %, about 50 wt % to about 70 wt %, about 55 wt % to about 70 wt %, about 10 wt % to about 65 wt %, about 15 wt % to about 65 wt %, about 20 wt % to about 65 wt %, about 25 wt % to about 65 wt %, about 30 wt % to about 65 wt %, about 35 wt % to about 65 wt %, about 40 wt % to about 65 wt %, about 45 wt % to about 65 wt %, about 50 wt % to about 65 wt %, and/or about 55 wt % to about 65 wt %.

### Organic Acid

The organic acid may serve to control the etch rate of at least a portion of the metal-containing film.

The organic acid may include a monocarboxylic acid, a dicarboxylic acid, a tricarboxylic acid, and/or a combination thereof.

Each of the monocarboxylic acid, dicarboxylic acid, and tricarboxylic acid may have a carbon number of about 1 to about 31, about 1 to about 20, or about 1 to about 10. According to at least one example embodiment, the organic acid may include:
HCOOH;
an aliphatic compound having about 1 to about 30 carbon atoms (for example, about 1 to about 20 carbon atoms or about 1 to about 15 carbon atoms), or an aromatic compound having about 6 to about 30 carbon atoms (for example, about 6 to about 15 carbon atoms or about 6 to about 10 carbon atoms), substituted with at least one carboxylic acid (*—COOH) (for example, 1, 2 or 3 carboxylic acids); or
a combination thereof;
wherein at least one hydrogen of the aliphatic compound and the aromatic compound may optionally be additionally substituted with a hydroxyl group, a thiol group, an amino group, a C₁-C₁₀ alkyl group (for example, a C₁-C₈alkyl group), a C₁-C₁₀ alkoxy group (for example, a C₁-C₅ alkoxy group), a C₁-C₁₀ alkylthio group (for example, a C₁-C₅ alkylthio group), a di(C₁-C₁₀ alkyl)amino group (for example, a di(C₁-C₅ alkyl)amino group), a phenyl group, and/or a combination thereof.

According to at least one example embodiment, the aliphatic compound may be a saturated aliphatic compound (for example, an alkane, a cycloalkane, or the like) or an unsaturated aliphatic compound (for example, an alkene, an alkyne, a cycloalkene, or the like).

According to at least one example embodiment, the aliphatic compound may be an acyclic aliphatic compound (for example, an alkane, an alkene, an alkyne, or the like) or a cyclic aliphatic compound (for example, a cycloalkane, a cycloalkene, adamantane, norbornane, or the like).

According to at least one example embodiment, the aliphatic compound may be a straight-chain aliphatic compound (for example, CH₃—CH₂—CH₂—CH₂—CH₃, or the like) or a branched aliphatic compound (for example, CH₃—CH(CH₃)—CH₂—CH₃, CH₃—C(CH₃)₂—CH₃, or the like).

According to at least one example embodiment, the aromatic compound may be benzene.

According to at least one example embodiment, the organic acid may include formic acid, acetic acid, propionic acid, butyric acid, valeric acid, lauric acid, oxalic acid, malonic acid, glutaric acid, adipic acid, gallic acid, succinic acid, malic acid, maleic acid, crotonic acid, fumaric acid, ascorbic acid, glutamic acid, citric acid, tartaric acid, glycolic acid, lactic acid, benzoic acid, salicylic acid, and/or a combination thereof.

The content of the organic acid may be about 0.1 wt % to about 15 wt %, about 0.5 wt % to about 15 wt %, about 1 wt % to about 15 wt %, about 3 wt % to about 15 wt %, about 5 wt % to about 15 wt %, about 7 wt % to about 15 wt %, about 0.1 wt % to about 13 wt %, about 0.5 wt % to about 13 wt %, about 1 wt % to about 13 wt %, about 3 wt % to about 13 wt %, about 5 wt % to about 13 wt %, and/or about 7 wt % to about 13 wt %, based on 100 wt % of the composition.

### Etching Controller

The etching controller serves, together with the organic acid, to control the etch rate and other characteristics by interacting with various metal atoms in the metal-containing film to be treated.

The etching controller may include a nitrogen-containing compound.

According to at least one example embodiment, the nitrogen-containing compound may not include a hydroxyl group.

According to at least one example embodiment, the etching controller may include a hydroxyl-free and nitrogen-containing compound. The term “hydroxyl-free nitrogen-containing compound” as used herein refers to a compound that does not contain a hydroxyl group and contains at least one nitrogen atom as a molecular constituent.

According to at least one example embodiment, the nitrogen-containing compound may include an amine-containing alcohol, an amine-containing acid, a polyalkylene polyamine (for example, a compound represented by Formula 5, or the like), a cyclic group-containing amine (for example, a compound represented by Formula 6, or the like), a polymer having a nitrogen-containing repeating unit, and/or a combination thereof.

According to at least one example embodiment, the nitrogen-containing compound may include a compound represented by Formula 5, a compound represented by the Formula 6, and/or a combination thereof:

$${T}_{52} - [ {( {L}_{5} )}_{a 5} ] - {T}_{51} \qquad Formula 5$$

$${CY}_{6} - {[ {L}_{6} - N ( {R}_{61} ) ( {R}_{62} ) ]}_{a 6} \qquad Formula 6$$

In Formula 5, L₅ is *—C(Z₅₁)(Z₅₂)—**, *—N(Z₅₃)—**, *—C(═O)—*′ or *—O—**,
In Formula 5, a5 is an integer from 1 to 30, In Formula 5, T₅₁ is *—N(R₅₁)(R₅₂),
In Formula 5, T₅₂ is *—N(R₅₃)(R₅₄), *—OH, *—SH, or *—C(═O)—OH,
In Formula 6, the ring CY₆ is a carbocyclic group having 5 to 20 carbon atoms or a heterocyclic group having 2 to 20 carbon atoms,
In Formula 6, L₆ is a single bond or a C₁-C₃₀ alkylene group,
In Formula 6, a₆ is an integer from 1 to 5,
In Formulae 5 and 6, Z₅₁, Z₅₂, Z₅₃, R₅₁, R₅₂, R₅₃, R₅₄, R₆₁ and R⁶² are each independently, hydrogen; an amino group; *—OH; *—SH; *—C(—O)—OH; a C₁-C₃₀ alkyl group, unsubstituted or substituted with an amino group, a di(C₁-C₃₀ alkyl)amino group, *—C(═O)—N(Q₅₁)(Q₅₂), *—OH, *—SH, *—C(═O)—OH; and/or a combination thereof;
Q₅₁ and Q₅₂ are each independently,
hydrogen; or a C₁-C₃₀ alkyl group, unsubstituted or substituted with an amino group, a di(C₁-C₃₀ alkyl)amino group, and/or a combination thereof; and
each of the symbols * and *′ represents a bonding site with a neighboring atom.

According to at least one example embodiment, each L₅ in Formula 5 may be *—C(Z₅₁)(Z₅₂)—**.

In at least one example embodiment, each L₅ in Formula 5 may be *—C(Z₅₁)(Z₅₂)—**, *—C(═O)—*′ or *—O—*′.

According to at least one example embodiment, each L₅ in Formula 5 may be *—C(Z₅₁)(Z₅₂)—*′ or *—N(Z₅₃)—*′.

According to at least one example embodiment, each L₅ in Formula 5 may be *—C(Z₅₁)(Z₅₂)—*′ or *—N(Z₅₃)—*′, and at least one L₅ may be *—N(Z₅₃)—*′.

According to at least one example embodiment, a5 in Formula 5 may be an integer from 1 to 25, an integer from 1 to 20, an integer from 1 to 15, an integer from 1 to 11, an integer from 2 to 25, an integer from 2 to 20, an integer from 2 to 15, or an integer from 2 to 11.

According to at least one example embodiment, each L₅ in Formula 5 may be *—C(Z₅₁)(Z₅₂)—*′, and a5 may be an integer from 1 to 11 or from 2 to 11.

According to at least one example embodiment, each L₅ in Formula 5 may be *—C(Z₅₁)(Z₅₂)—**, *—C(═O)—*′ or *—O—*′, and a5 may be an integer from 2 to 11.

According to at least one example embodiment, each L₅ in Formula 5 may be *—C(Z₅₁)(Z₅₂)—*′ or *—N(Z₅₃)—*′, and a5 may be an integer from 5 to 11.

According to at least one example embodiment, each L₅ in Formula 5 may be *—C(Z₅₁)(Z₅₂)—*′ or *—N(Z₅₃)—*′, and the number of *—N(Z₅₃)—*′ may be 1, 2, 3 or 4.

According to at least one example embodiment, T₅₂ of Formula 5 may be *—N(R₅₃)(R₅₄).

According to at least one example embodiment, T₅₂ in Formula 5 may be *—OH or *—C(═O)—OH.

According to at least one example embodiment, the ring CY₆ in Formula 6 may be a saturated or unsaturated carbocyclic group having 5 to 15 carbon atoms or 5 to 10 carbon atoms, or a saturated or unsaturated heterocyclic group having 2 to 15 carbon atoms or 2 to 10 carbon atoms.

According to at least one example embodiment, the ring CY₆ in Formula 6 may be a cyclopentane group, a cyclohexane group, a cycloheptane group, a cyclooctane group, a cyclopentene group, a cyclohexene group, a cycloheptene group, a cyclooctene group, a benzene group, a naphthalene group, a piperazine group, a pyrrolidine group, a piperidine group, an azepane group, a tetrahydrofuran group, a tetrahydrothiophene group, a tetrahydro-2H-pyran group, a tetrahydro-2H-thiopyran group, a pyrazole group, an imidazole group, a triazole group, a 4H-pyran-4-one group, a pyridine group, a pyrimidine group, a pyrazine group, a pyridazine group, a triazine group, a carbazole group, a dibenzofuran group or a dibenzothiophene group.

According to at least one example embodiment, L₆ in Formula 6 may be a single bond or a C₁-C₁₀ alkylene group (for example, a C₁-C₅ alkylene group).

According to at least one example embodiment, a₆ in Formula 6 may be 1 or 2.

According to at least one example embodiment, in Formulae 5 and 6, Z₅₁, Z₅₂, Z₅₃, R₅₁, R₅₂, R₅₃, R₅₄, R₆₁ and R₆₂ may each independently be, hydrogen; an amino group; or a C₁-C₃₀ alkyl group, unsubstituted or substituted with an amino group, a di(C₁-C₃₀ alkyl)amino group, *—C(═O)—N(Q₅₁)(Q₅₂), and/or a combination thereof; and

Q₅₁ and Q₅₂ may each independently be, hydrogen; or a C₁-C₃₀ alkyl group, unsubstituted or substituted with an amino group, a di(C₁-C₃₀ alkyl)amino group, and/or a combination thereof.

According to at least one example embodiment, in Formulae 5 and 6, Z₅₁, Z₅₂, Z₅₃, R₅₁, R₅₂, R₅₃, R₅₄, R₆₁ and R₆₂ may each independently be, hydrogen; an amino group; or a C₁-C₁₀ alkyl group, unsubstituted or substituted with an amino group, a di(C₁-C₁₀ alkyl)amino group, *—C(═O)—N(Q₅₁)(Q₅₂), and/or a combination thereof; and

Q₅₁ and Q₅₂ may each independently be, hydrogen; or a C₁-C₁₀ alkyl group, unsubstituted or substituted with an amino group, a di(C₁-C₁₀ alkyl)amino group, and/or a combination thereof.

According to at least one example embodiment, the nitrogen-containing compound may include a compound represented by Formula 51:

$${T}_{52} - {\{ {[ C ( {Z}_{51} ) ( {Z}_{52} ) ]}_{a 51} - N ( {Z}_{53} ) \}}_{b 51} - {[ C ( {Z}_{54} ) ( {Z}_{55} ) ]}_{a 52} - {T}_{51} \qquad Formula 51$$

In Formula 51,
the definitions of T₅₁, T₅₂, Z₅₁, Z₅₂ and Z₅₃ are each the same as described herein,
the definitions of Z₅₄ and Z₅₅ are each the same as the definition of Z₅₁ described herein,
a51 and a52 are, independently of each other, integers from 2 to 5 (for example, 2 or 3), and
b51 is an integer from 1 to 7 (for example, 1, 2, or 3).

According to at least one example embodiment, the nitrogen-containing compound may include at least one of the following compounds A1 to A32:

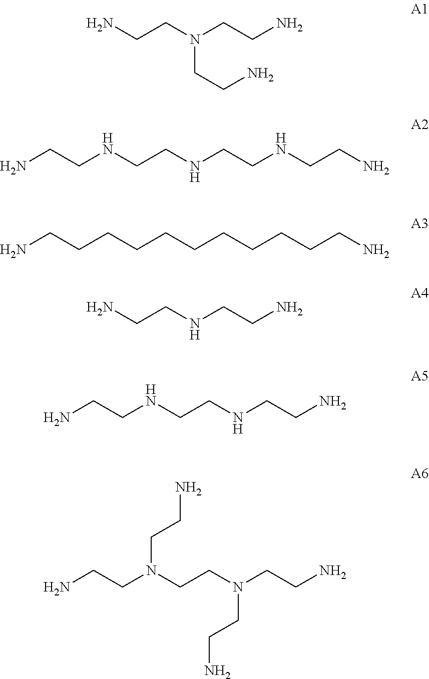 [SMILES: NCCN(CCN)CCN ; NCCNCCNCCNCCN ; NCCCCCCCCCCCN ; NCCNCCN ; NCCNCCNCCN ; NCCN(CCN)CCN(CCN)CCN]

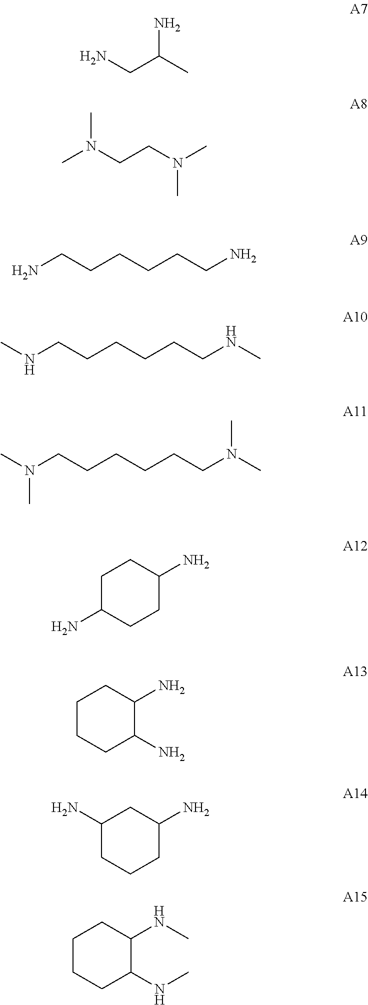

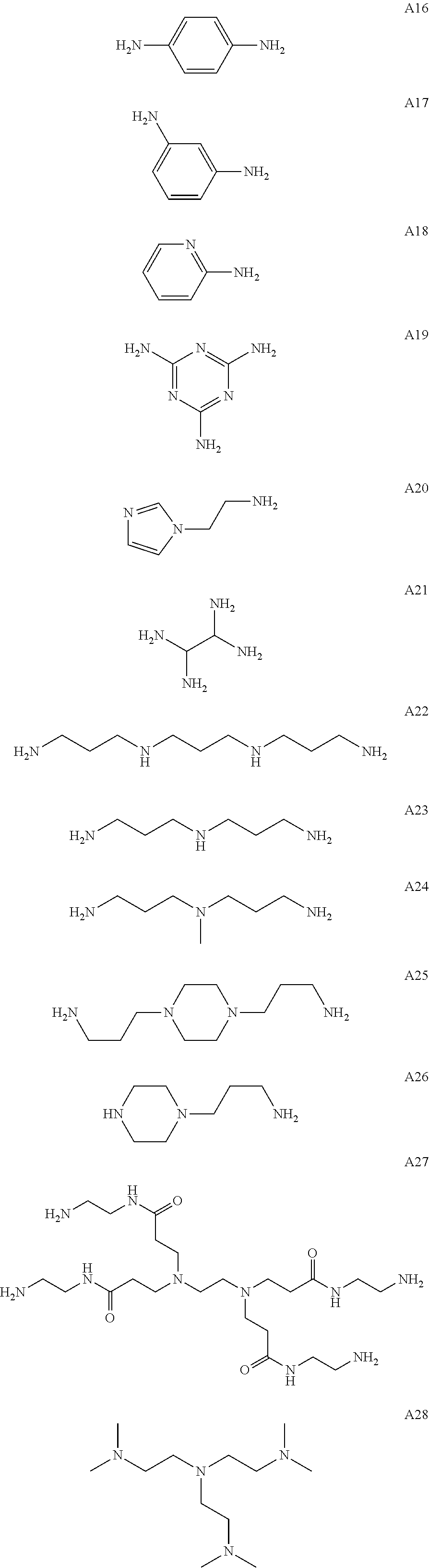

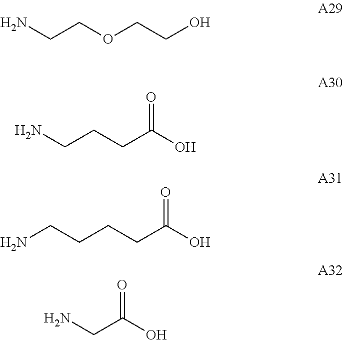

According to at least one example embodiment, the nitrogen-containing compound may include a polymer having a nitrogen-containing repeating unit (for example, a polymer having a hydroxyl-free and nitrogen-containing repeating unit). The polymer may be a water-soluble polymer. As another example, the polymer may be a homopolymer.

According to at least one example embodiment, the nitrogen-containing compound may include a polyallylamine-based polymer (for example, a hydroxyl-free polyallylamine-based polymer).

The nitrogen-containing repeating unit may include a repeating unit represented by Formula 1-1, a repeating unit represented by Formula 1-2, a repeating unit represented by Formula 1-3, a repeating unit represented by Formula 1-4, and/or a combination thereof:

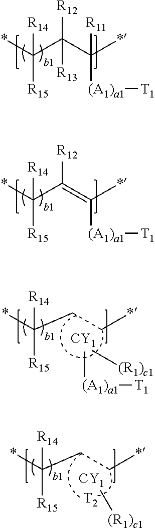

In Formulae 1-1 to 1-3, A₁ may be *—C(R₁₆)(R₁₇)—*′, *—N(R₁₆)—**, *—C(═O)—**, *—O—*′, or *—S—**.

In Formulae 1-1 to 1-3, a1 is an integer from 0 to 20, and when a1 is 2 or more, two or more A₁s may be the same or different from each other. When a1 is 0, *-(A₁)ₙ₁-*′ becomes a single bond.

According to at least one example embodiment, a1 may be 0.

According to at least one example embodiment, a1 may be great than 0.

According to at least one example embodiment, a1 may be an integer from 0 to 10.

According to at least one example embodiment, a1 may be an integer from 1 to 5.

In Formulae 1-1 to 1-4, b1 is an integer from 0 to 10, and when b1 is 2 or more, two or more *—C(R₁₄)(R₁₅)—*′ groups may be the same as or different from each other. When b₁ is 0, *—C(R₁₄)(R₁₅)—*′ becomes a single bond.

According to at least one example embodiment, b₁ may be an integer from 0 to 5.

In Formulae 1-1 to 1-3, T₁ may be *—N(Z₁₁)(Z₁₂), *—[N(Z₁₁)(Z₁₂)(Z₁₃)]⁺[Z₁₄]⁻, a group represented by Formula AN, or a group represented by Formula BN:

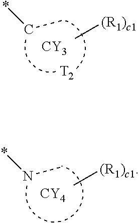

In Formulae 1-3, 1-4, AN and BN, each of the rings CY₁ to CY₄ may independently be a cyclic group having 2 to 10 carbon atoms.

According to at least one example embodiment, in Formulae 1-1 to 1-3, T₁ may be *—N(Z₁₁)(Z₁₂) or *—[N(Z₁₁)(Z₁₂)(Z₁₃)]⁺[Z₁₄]⁻, where each of Z₁₁ to Z₁₃ may be hydrogen.

According to at least one example embodiment, in Formulae 1-1 to 1-3, T₁ may be *—N(Z₁₁)(Z₁₂) or *—[N(Z₁₁)(Z₁₂)(Z₁₃)]⁺[Z₁₄]⁻; where Z₁₁ may be hydrogen and Z₁₂ may be an atom other than hydrogen (e.g., may not be hydrogen).

According to at least one example embodiment, in Formulae 1-1 to 1-3, T₁ may be *—N(Z₁₁)(Z₁₂) or *—[N(Z₁₁)(Z₁₂)(Z₁₃)]⁺[Z₁₄]⁻, where each of Z₁₁ and Z₁₂ may be an atom other than hydrogen (e.g., may not be hydrogen).

According to at least one example embodiment, in Formulae 1-1 to 1-3, T₁ may be *—[N(Z₁₁)(Z₁₂)(Z₁₃)]⁺[Z₁₄]⁻, where each of Z₁₁ to Z₁₃ may be an atom other than hydrogen (e.g., may not be hydrogen).

According to at least one example embodiment, in Formulae 1-1 to 1-3, T₁ may be a group represented by Formula AN, and in T₂ of Formula AN, Z₁₁ and Z₁₂ may be hydrogen.

According to at least one example embodiment, in Formulae 1-1 to 1-3, T₁ may be a group represented by Formula AN, and in T₂ of Formula AN, Z₁₁ may be an atom other than hydrogen (e.g., may not be hydrogen).

According to at least one example embodiment, in Formulae 1-1 to 1-3, T₁ may be a group represented by Formula AN, and T₂ in Formula AN may be *—[N(Z₁₁)(Z₁₂)]⁺[Z₁₄]⁻*′, where each of Z₁₁ and Z₁₂ may be an atom other than hydrogen (e.g., may not be hydrogen).

According to at least one example embodiment, in T₂ of Formula 1-4, Z₁₁ and Z₁₂ may be hydrogen.

According to at least one example embodiment, in T₂ of Formula 1-4, Z₁₁ may not be hydrogen, and Z₁₂ may be hydrogen.

According to at least one example embodiment, T₂ in Formula 1-4 may be *—[N(Z₁₁)(Z₁₂)]⁺[Z₁₄]⁻*′, and each of Z₁₁ and Z₁₂ may be an atom other than hydrogen (e.g., may not be hydrogen).

In Formulae 1-3, 1-4, AN and BN, cl represents the number of R₁ and may be selected from an integer from 0 to 10. When cl is 2 or more, two or more R₁ may be the same or different from each other.

In Formulae 1-4 and AN, T₂ may be *—N(Z₁₁)—*′ or *—[N(Z₁₁)(Z₁₂)]⁺[Z₁₄]⁻*′. For a definition of each of Z₁₁, Z₁₂ and Z₁₄, reference is made to the descriptions herein.

According to at least one example embodiment, in Formula 1-3, CY₁ may be a cyclopropane group, a cyclobutane group, a cyclopentane group, a cyclohexane group, a cycloheptane group, a cyclooctane group, an oxirane group, an oxetane group, a tetrahydrofuran group, or a tetrahydropyran group.

According to at least one example embodiment, in Formula 1-4, the ring CY₂ may be a saturated cyclic group having 4, 5, 6 or 7 carbon atoms.

According to at least one example embodiment, in Formula AN,
i) T₂ may be *—N(Z₁₁)—*′, and the ring CY₃ may be a pyrrole group, an imidazole group, a pyrazole group, an aziridine group, an azetidine group, a pyrrolidine group, or a piperidine group, or
ii) T₂ may be *—[N(Z₁₁)(Z₁₂)]⁺[Z₁₄]⁻*′, and the ring CY₃ may be a saturated cyclic group having 4, 5, 6 or 7 carbon atoms.

According to at least one example embodiment, in Formula BN, the ring CY₄ may be a pyrrole group, an imidazole group, a pyrazole group, an aziridine group, an azetidine group, a pyrrolidine group, or a piperidine group.

Each of R₁, R₁₁ to R₁₇ and Z₁₁ to Z₁₃ may independently be, hydrogen, *—F, *—Cl, *—Br, *—I, *—SH, *—C(═O)—Q₁, *—NH—C(═O)—Q₁, *—C(═O)—O—Q₁, *—SO₂—Q₁, *—P(═O)-(Q₁) (Q₂), *—N(Q₁) (Q₂), or *—[N(Q₁) (Q₂) (Q₃)]⁺[Q₄]; or
a C₁-C₃₀ alkyl group, a C₁-C₃₀ alkoxy group, a C₂-C₃₀ alkenyl group, a C₃-C₃₀ carbocyclic group, or C₁-C₃₀ heterocyclic group, each unsubstituted or substituted with *—F, *—Cl, *—Br, *—I, *—SH, *—C(═O)—Q₁₁, *—NH—C(═O)—Q₁₁, *—C(═O)—O—Q₁₁, *—SO₂—Q₁₁, *—P(═O)-(Q₁₁) (Q₁₂), *—N(Q₁₁) (Q₁₂), *—[N(Q₁₁) (Q₁₂) (Q₁₃)]⁺[Q₁₄], a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, and/or a combination thereof.

Two or more of R₁, R₁₁, R₁₂, R₁₃, R₁₄, R₁₅, R₁₆, R₁₇, Z₁₁, Z₁₂ and Z₁₃ may optionally be combined with each other to form a cyclic group having 2 to 10 carbon atoms.

Each of Q₁ to Q₃ and Q₁₁ to Q₁₃ may independently be, hydrogen, *—F, *—Cl, *—Br, *—I, *—SH, *—C(═O)—H, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃) or *—N(CH₃)₂; or
a C₁-C₃₀ alkyl group, a C₁-C₃₀ alkoxy group, a C₂-C₃₀ alkenyl group, a C₃-C₃₀ carbocyclic group, or a C₁-C₃₀ heterocyclic group, each unsubstituted or substituted with *—F, *—Cl, *—Br, *—I, *—SH, *—C(═O)—H, *—C(═O)—NH₂, *—C(═O)—NH(CH₃), *—C(═O)—N(CH₃)₂, *—NH—C(═O)—NH₂, *—NH—C(═O)—NH(CH₃), *—NH—C(═O)—N(CH₃)₂, *—NH₂, *—NH(CH₃), *—N(CH₃)₂, a C₁-C₃₀ alkyl group, a C₁-C₃₀ alkoxy group, a C₂-C₃₀ alkenyl group, a C₃-C₃₀ carbocyclic group, a C₁-C₃₀ heterocyclic group, and/or a combination thereof.

The C₃-C₃₀ carbocyclic group may include, for example, a cyclopropyl group, a cyclobutyl group, a cyclopentyl group, a cyclohexyl group, a cycloheptyl group, a cyclooctyl group, a phenyl group, or a naphthyl group.

The C₁-C₃₀ heterocyclic group may include, for example, an oxiranyl group, an oxetanyl group, a tetrahydrofuranyl group, a tetrahydropyranyl group, a pyridinyl group, or a pyrimidinyl group.

Each of [Z₁₄]⁻, [Q₄]⁻ and [Q₁₄]⁻ may be an anion.

For example, each of [Z₁₄]⁻, [Q₄]⁻, and [Q₁₄]⁻ may independently be borate ([B(OH)₄]⁻), fluoride ([F]⁻), chloride ([C₁]⁻), bromide ([Br]⁻), iodide ([I]⁻), hydrogen sulfate ([HSO₄]⁻), nitrate ([NO₃]⁻), formate ([HCOO]⁻), acetate ([CH₃COO]⁻), or dihydrogen phosphate ([H₂PO₄]⁻).

Unless otherwise defined herein, each of the symbols * and *′ represents a bonding site with a neighboring atom.

According to at least one example embodiment, the repeating unit represented by Formula 1-3 may be a repeating unit represented by one of Formulae 1-3(1) to 1-3(8):

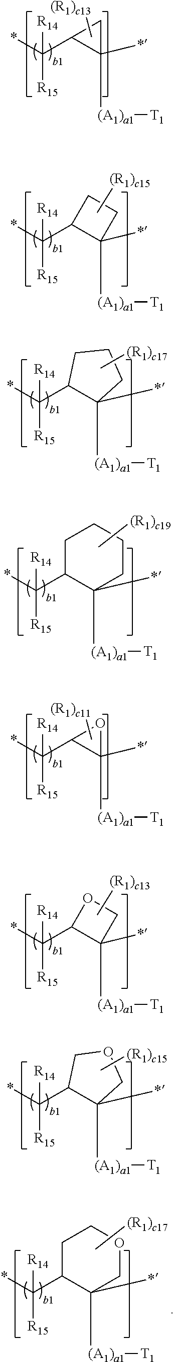

In Formulae 1-3(1) to 1-3(8), the definitions of A₁, a1, b1, T₁, R₁, R₁₄ and R¹⁵ are each the same as described herein, c11 is 0 or 1, c13 is an integer from 0 to 3, c15 is an integer from 0 to 5,
c17 is an integer from 0 to 7, c19 is an integer from 0 to 9, and each of the symbols * and *′ represents a bonding site with a neighboring atom.

According to at least one example embodiment, the repeating unit represented by Formula 1-4 may be a repeating unit represented by one of Formulas 1-4(1) to 1-4(3):

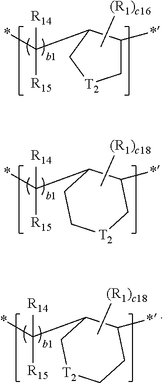

In Formulae 1-4(1) to 1-4(3), the definitions of b1, R₁, R₁₄, R₁₅ and T₂ are each the same as described herein, c16 is an integer from 0 to 6, c18 is an integer from 0 to 8, and each of the symbols * and *′ represents a bonding site with a neighboring atom.

According to at least one example embodiment, the group represented by Formula AN may be a group represented by one of Formulae AN(1) to AN(12):

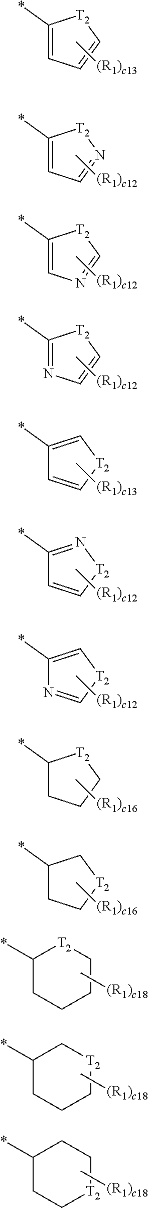

In Formulae AN(1) to AN(12), the definitions of R₁ and T₂ are each the same as those described herein, c12 is an integer from 0 to 2, c13 is an integer from 0 to 3, c16 is an integer from 0 to 6, c18 is an integer from 0 to 8, and the symbol * represents a bonding site with a neighboring atom.

According to at least one example embodiment, the group represented by Formula BN may be a group represented by one of Formulae BN(1) to BN(7):

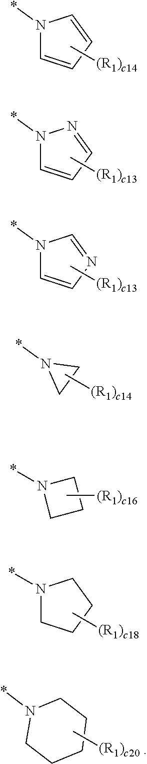

In Formulae BN(1) to BN(7), the definition of R₁ is the same as described herein, c13 is an integer from 0 to 3, c14 is an integer from 0 to 4, c16 is an integer from 0 to 6, c18 is an integer from 0 to 8, c20 is an integer from 0 to 10, and the symbol * represents a bonding site with a neighboring atom.

According to at least one example embodiment, the nitrogen-containing repeating unit may include a repeating unit represented by Formula 1-1, wherein in Formula 1-1, A₁ is *—C(R₁₆)(R₁₇)—*′, a1 is an integer from 1 to 5, b1 is an integer from 0 to 5, T₁ is *—N(Z₁₁)(Z₁₂) or *—[N(Z₁₁)(Z₁₂)(Z₁₃)]⁺[Z₁₄]⁻, and the definitions of R₁₁ to R₁₇, Z₁₁ to Z₁₃ and [Z₁₄]⁻ may each be the same as described herein.

The weight-average molecular weight of the polymer having a nitrogen-repeating unit may be, for example, from about 200 g/mol to about 100,000 g/mol. The weight-average molecular weight may be measured, for example, using gel permeation chromatography (GPC), and may be a value calculated based on polystyrene standards.

According to at least one example embodiment, the polymer having a nitrogen-repeating unit may be any one of Polymers 1 to 259:

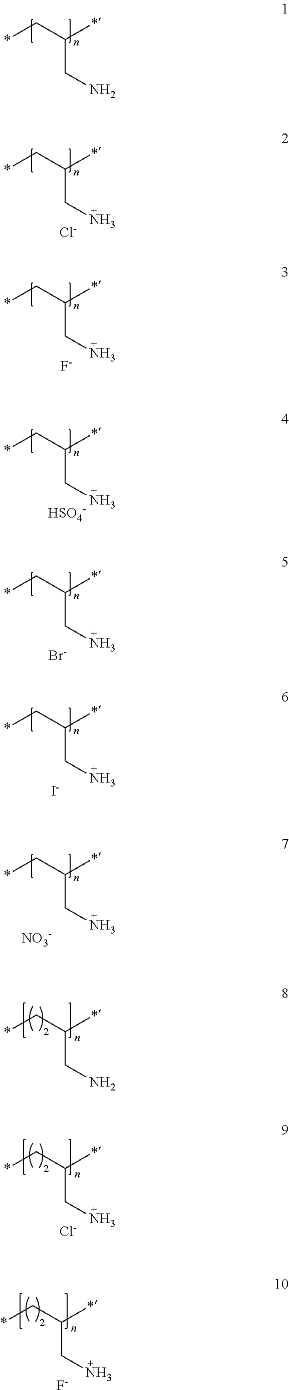

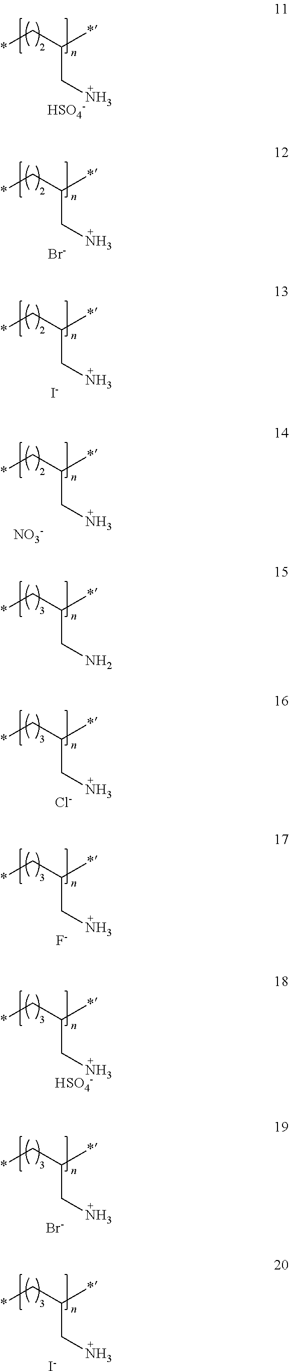

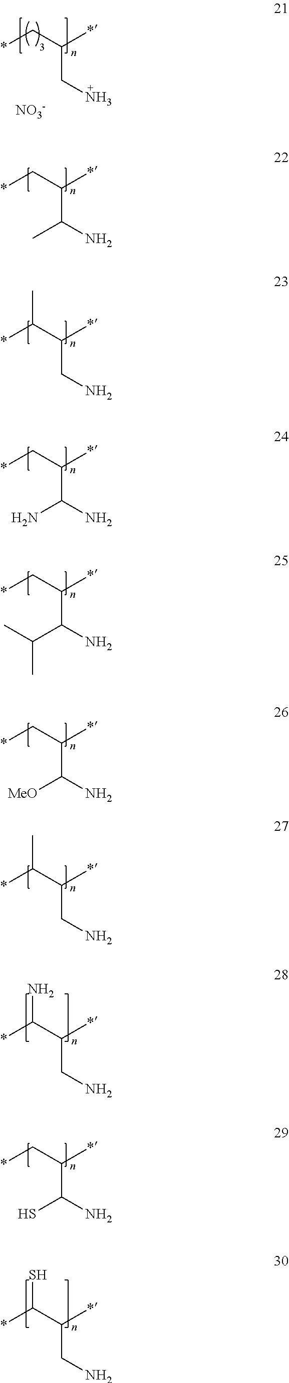

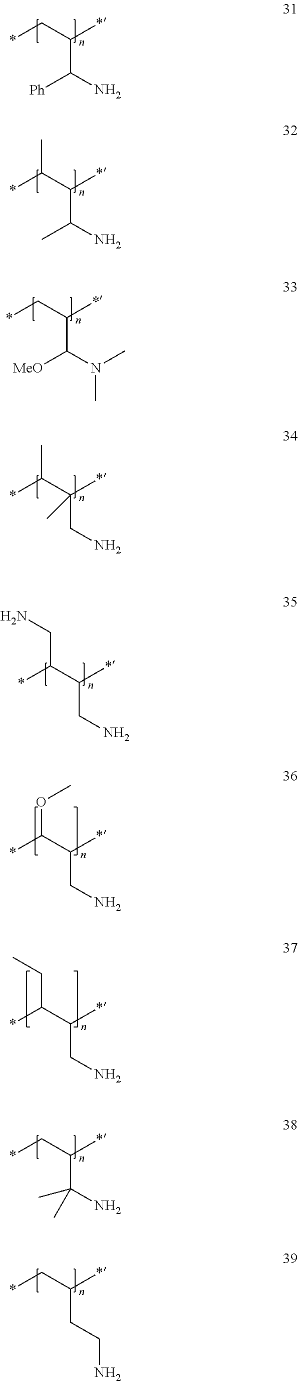

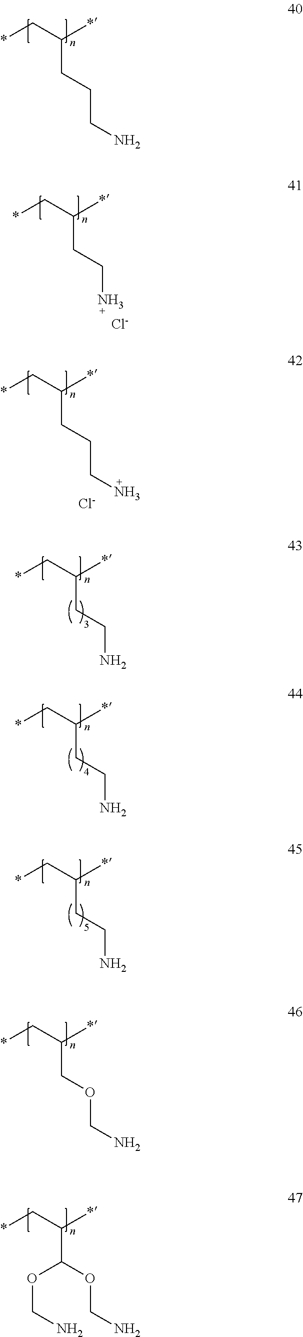

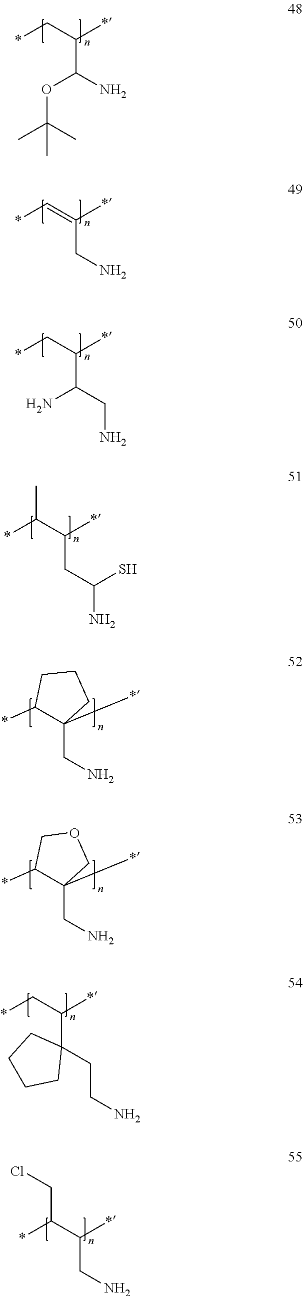

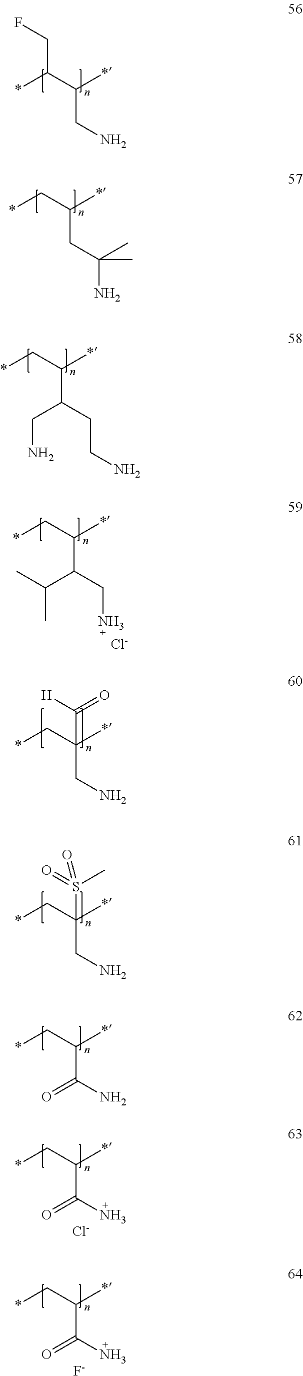

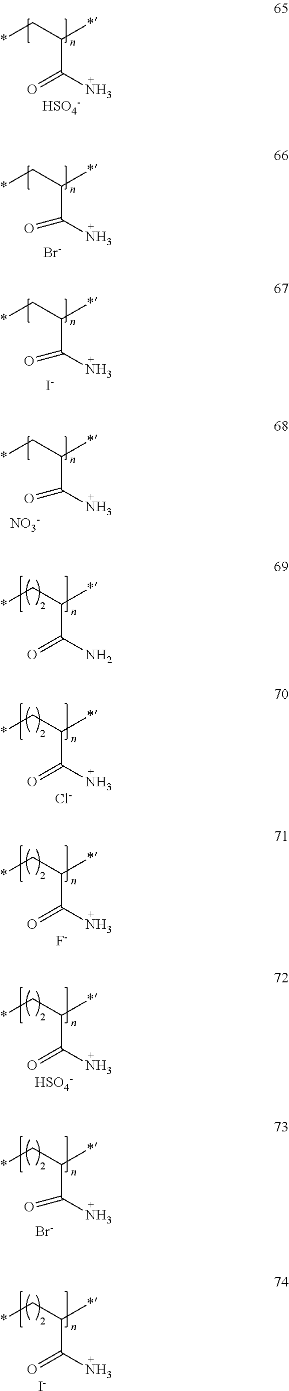

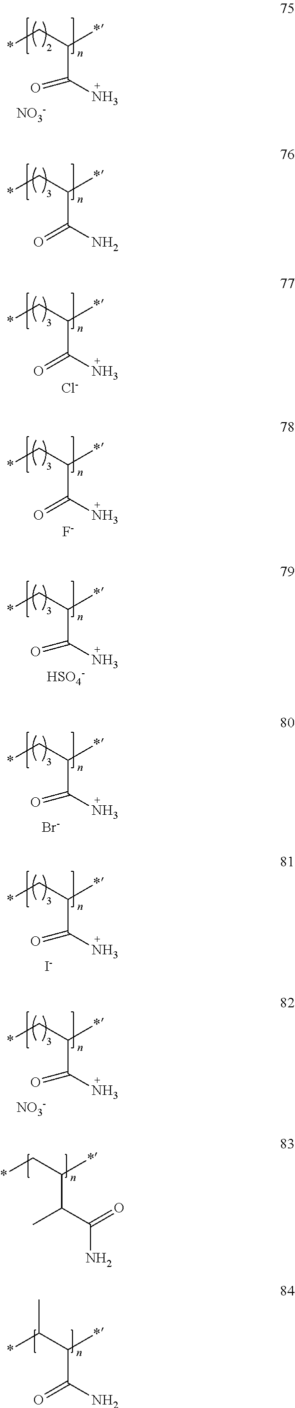

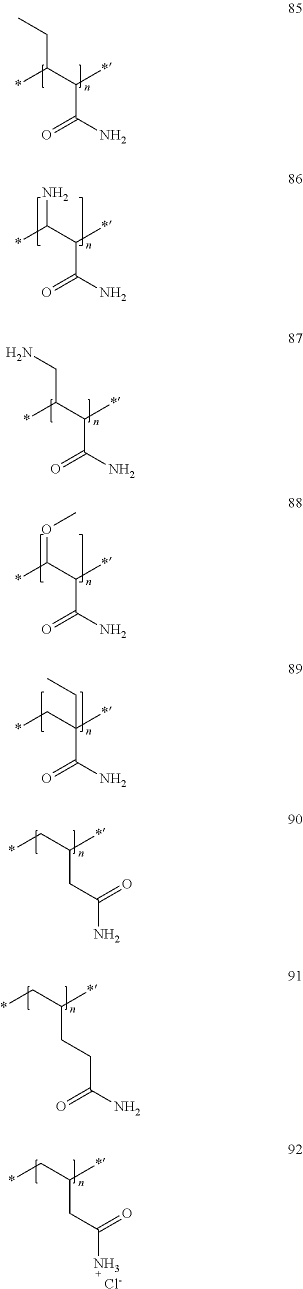

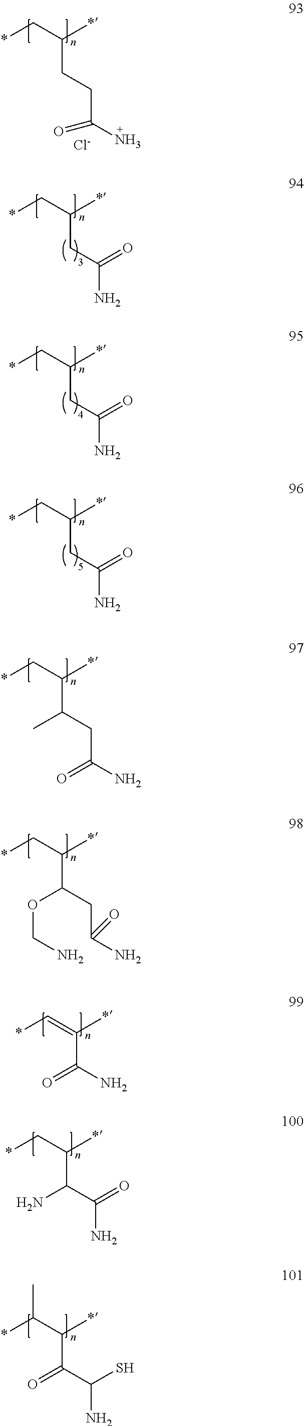

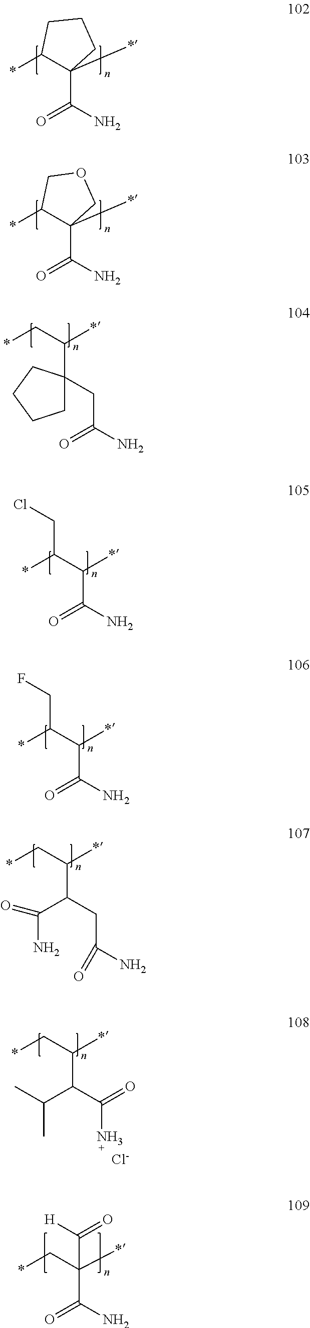

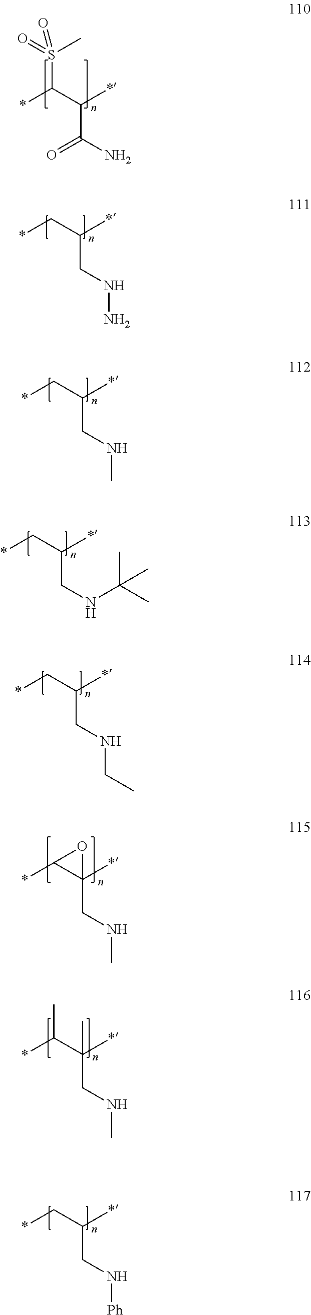

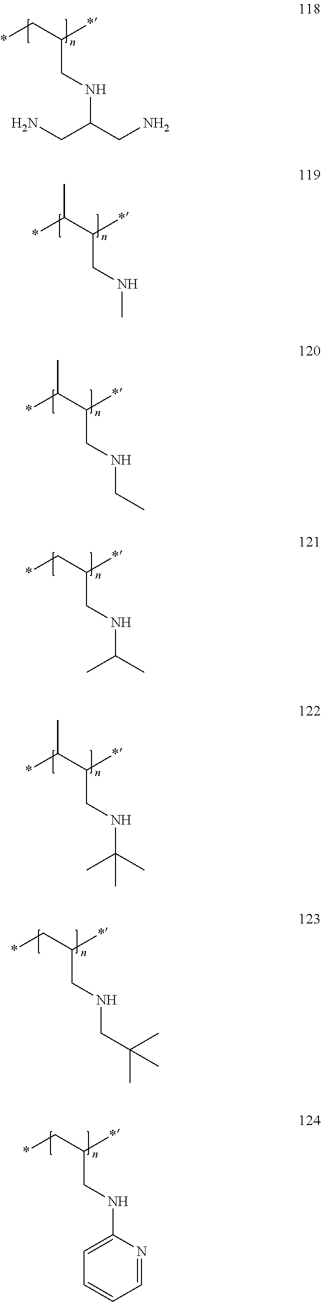

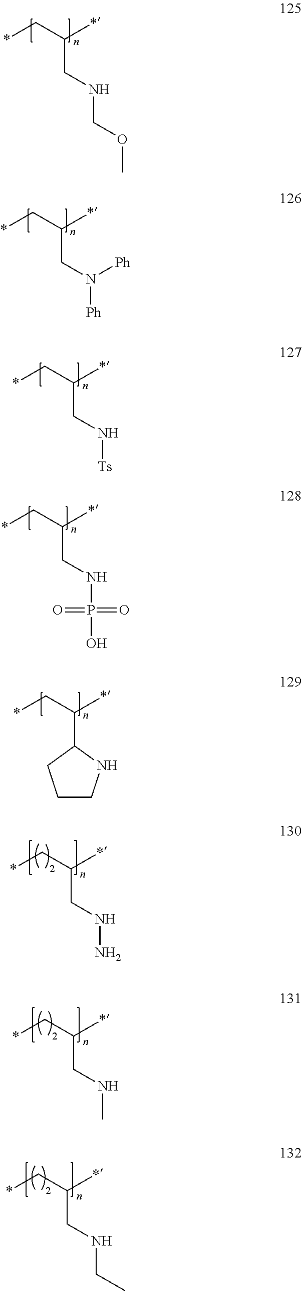

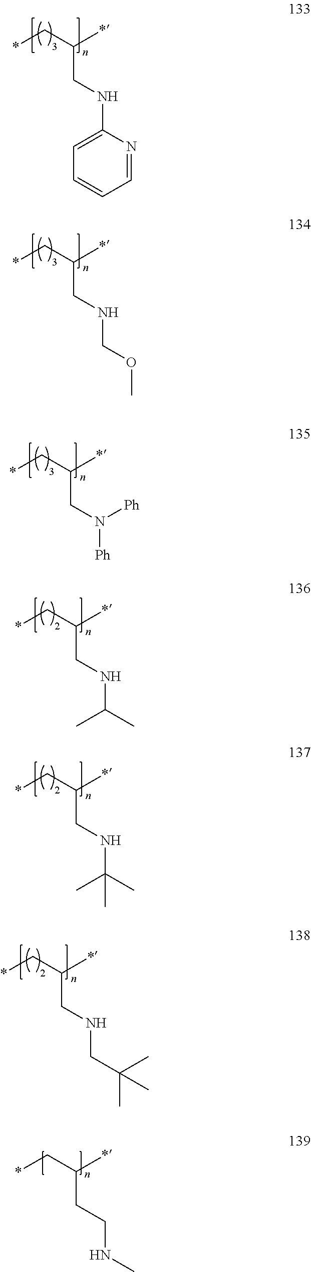

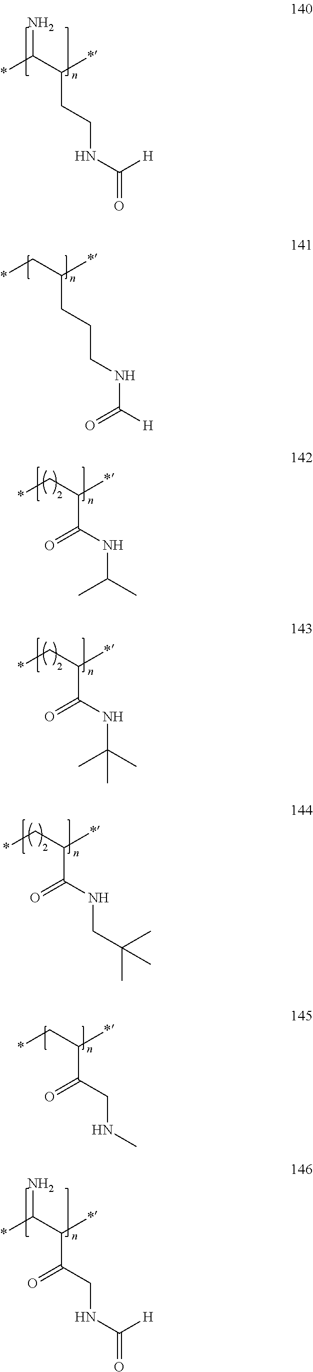

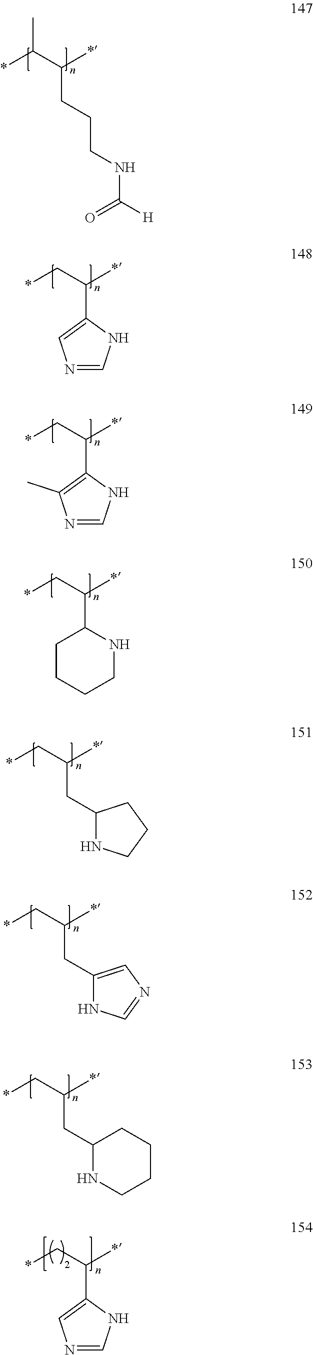

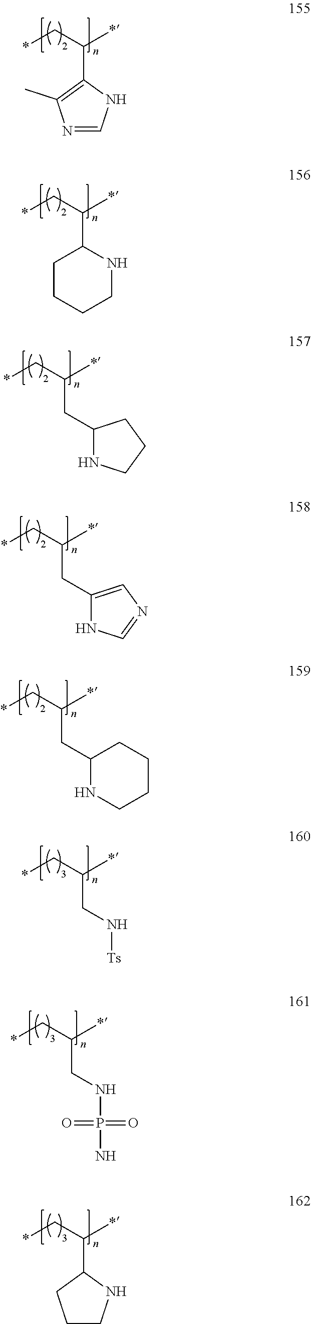

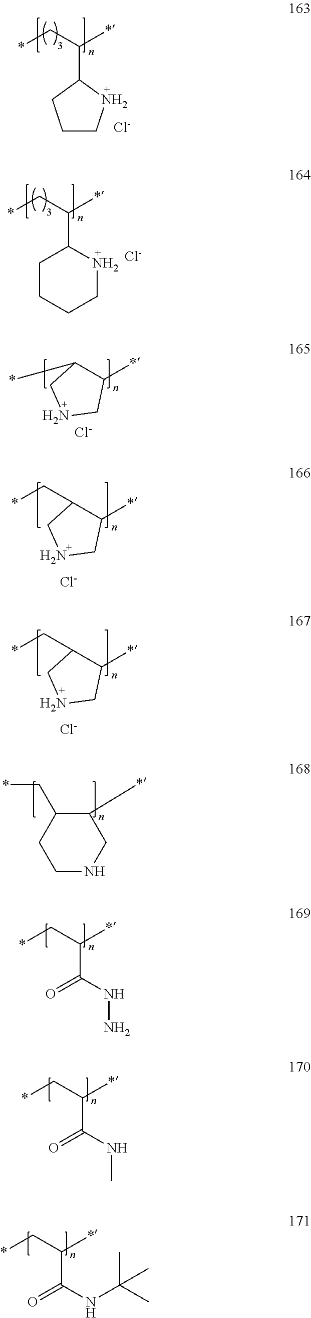

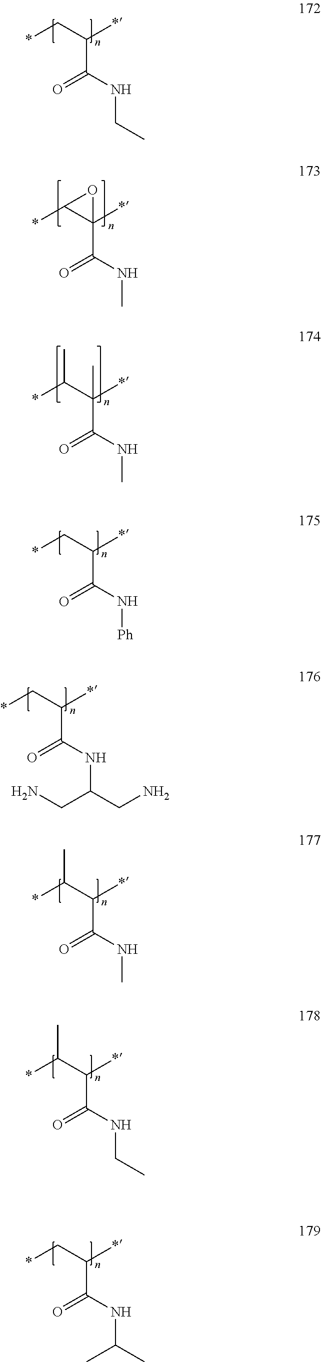

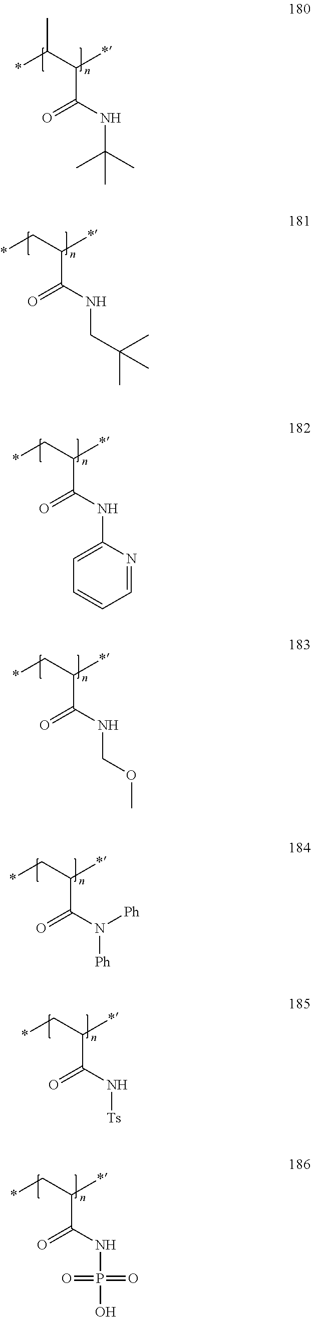

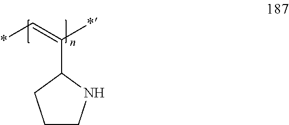

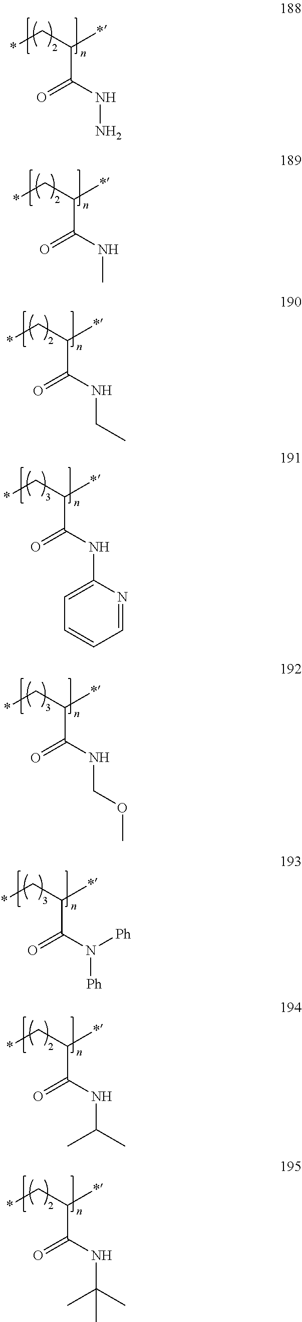

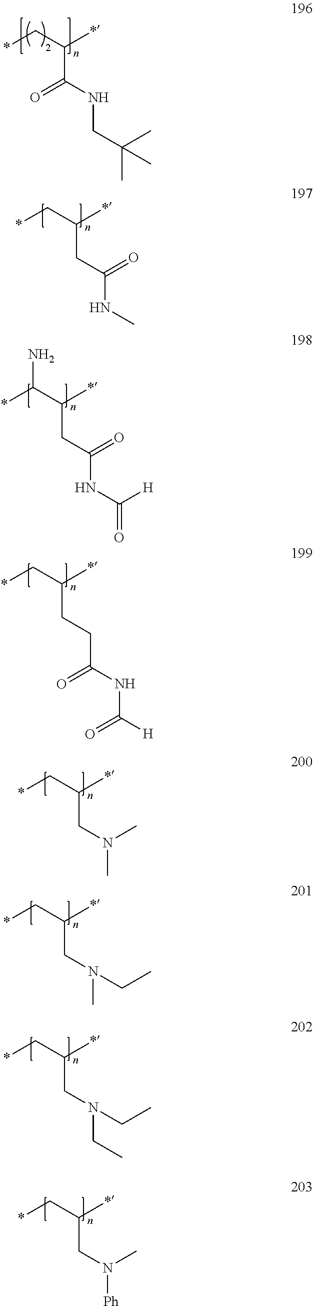

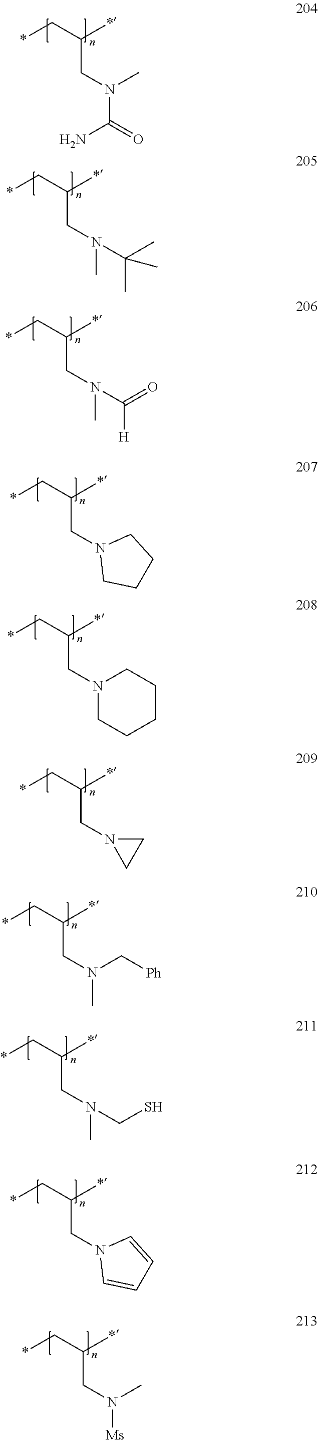

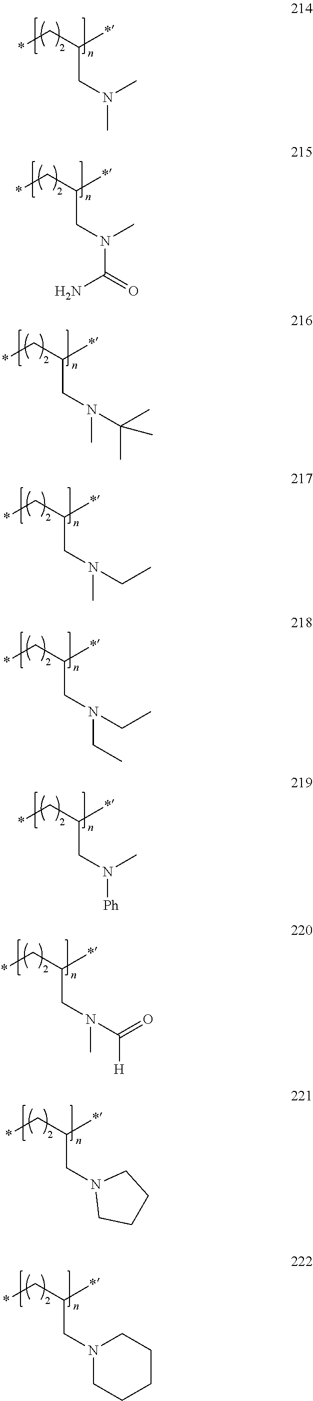

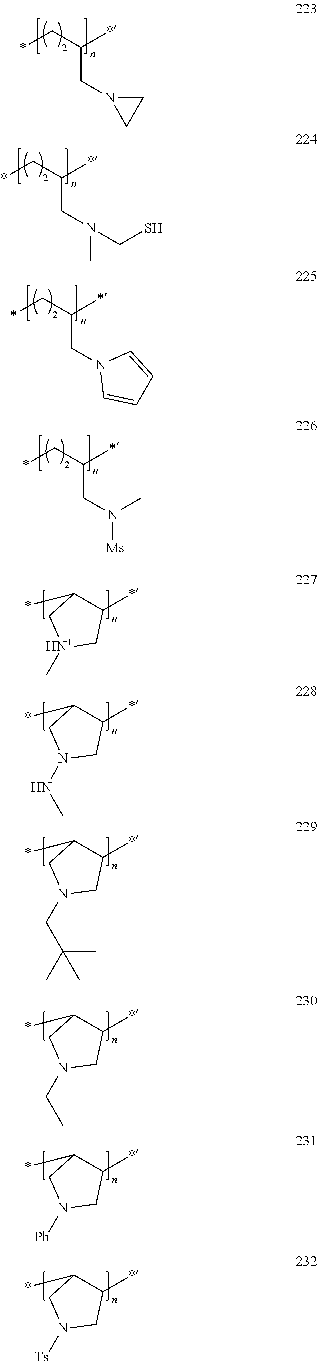

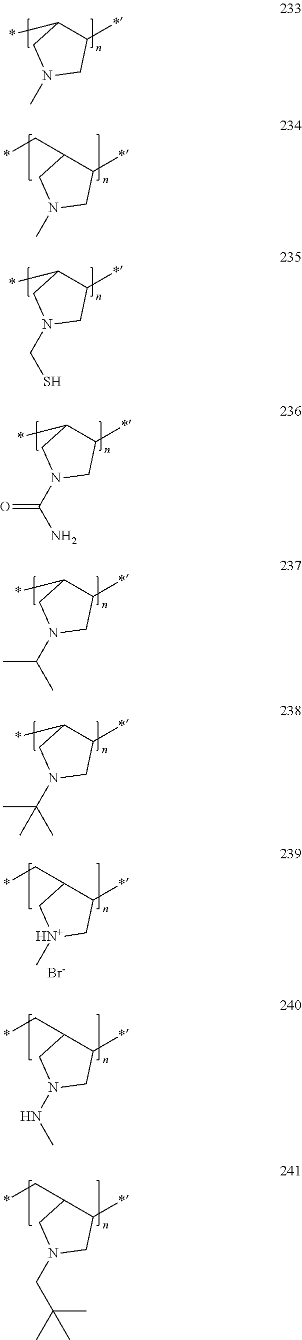

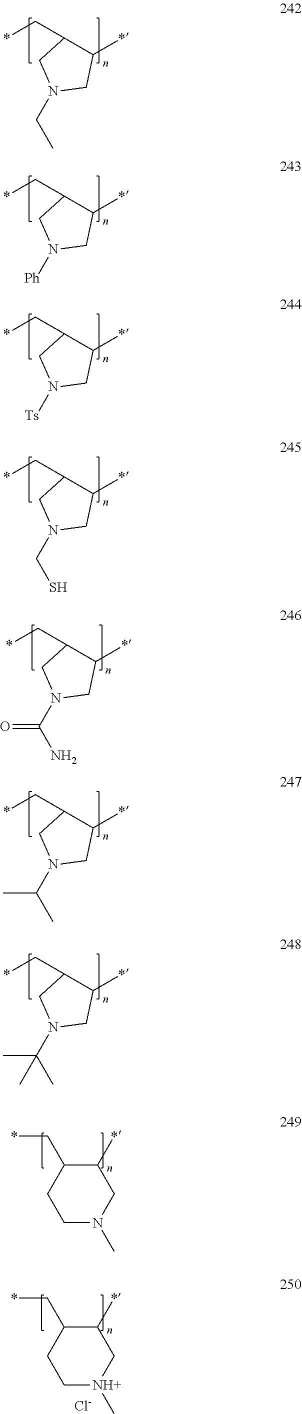

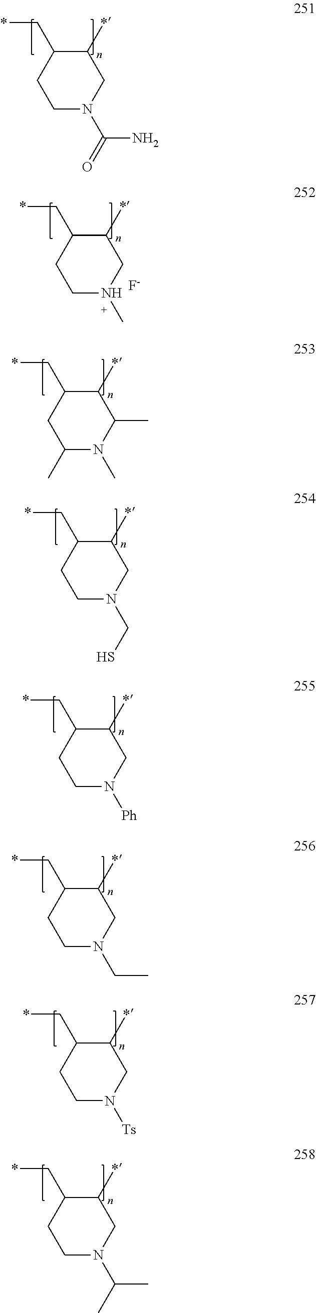

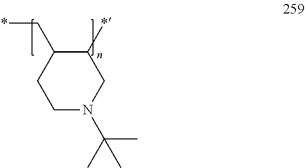

In Polymers 1 to 259, OMe is a methoxy group, Ph is phenyl group, Ts is toluenesulfonyl group (*—S(═O)₂—(C₆H₄)—CH₃), Ms is methylsulfonyl group (*—S(═O)₂—CH₃), n is selected from 2 to 10,000, and each of the symbols * and *′ represents a bonding site with a neighboring atom.

The Polymers 1 to 259 may have a weight-average molecular weight in the range as described herein.

The content (by weight) of the etching controller may be, based on 100 wt % of the composition, about 0.01 wt % to about 5 wt %, about 0.01 wt % to about 4 wt %, about 0.01 wt % to about 3 wt %, about 0.01 wt % to about 2 wt %, about 0.01 wt % to about 1.5 wt %, about 0.01 wt % to about 1 wt %, about 0.05 wt % to about 5 wt %, about 0.05 wt % to about 4 wt %, about 0.05 wt % to about 3 wt %, about 0.05 wt % to about 2 wt %, about 0.05 wt % to about 1.5 wt %, about 0.05 wt % to about 1 wt %, about 0.1 wt % to about 5 wt %, about 0.1 wt % to about 4 wt %, about 0.1 wt % to about 3 wt %, about 0.1 wt % to about 2 wt %, about 0.1 wt % to about 1.5 wt %, about 0.1 wt % to about 1 wt %, about 0.5 wt % to about 5 wt %, about 0.5 wt % to about 4 wt %, about 0.5 wt % to about 3 wt %, about 0.5 wt % to about 2 wt %, and/or about 0.5 wt % to about 1.5 wt %. The content of the etching controller refers to the solid content of the polymer, when the polymer having a nitrogen-containing repeating unit is used as the etching controller.

The composition may have a pH of less than 1. For example, the pH of the composition as described above may be less than 1.0, less than or equal to 0.9, less than or equal to 0.7, less than or equal to 0.5, less than or equal to 0.3, less than or equal to 0.1, less than or equal to 0.0, or less than 0.0.

As another example, the pH of the composition may be about −3.0 to about 0.9, about −3.0 to about 0.7, about −3.0 to about 0.5, about −3.0 to about 0.3, about −3.0 to about 0.1, about −3.0 to about 0.0, about −2.5 to about 0.9, about −2.5 to about 0.7, about −2.5 to about 0.5, about −2.5 to about 0.3, about −2.5 to about 0.1, about −2.5 to about 0.0, about −2.0 to about 0.9, about −2.0 to about 0.7, about −2.0 to about 0.5, about −2.0 to about 0.3, about −2.0 to about 0.1, about −2.0 to about 0.0, about −1.5 to about 0.9, about −1.5 to about 0.7, about −1.5 to about 0.5, about −1.5 to about 0.3, about −1.5 to about 0.1, about −1.5 to about 0.0, about −1.0 to about 0.9, about −1.0 to about 0.7, about −1.0 to about 0.5, about −1.0 to about 0.3, about −1.0 to about 0.1, about −1.0 to about 0.0, about −0.5 to about 0.9, about −0.5 to about 0.7, about −0.5 to about 0.5, about −0.5 to about 0.3, or about −0.5 to about 0.1, or about −0.5 to about 0.0. By the composition having a pH within the ranges described above, the interaction between the etching controller and the metal atoms in the metal-containing film may be more smoothly achieved.

According to at least one example embodiment, the composition may include about 0.001 wt % to about 10 wt % of an oxidizing agent, about 10 wt % to about 70 wt % of phosphoric acid, about 0.1 wt % to about 15 wt % of an organic acid, and about 0.01 wt % to about 3 wt % of an etching controller.

According to at least one example embodiment, the composition may include about 0.001 wt % to about 5 wt % of an oxidizing agent, about 10 wt % to about 75 wt % of phosphoric acid, about 0.1 wt % to about 13 wt % of an organic acid, and about 0.01 wt % to about 5 wt % of an etching controller.

According to at least one example embodiment, the composition may include about 0.001 wt % to about 5 wt % of an oxidizing agent, about 10 wt % to about 70 wt % of phosphoric acid, about 0.1 wt % to about 15 wt % of an organic acid, and about 0.01 wt % to about 5 wt % of an etching controller.

According to at least one example embodiment, the composition may be used in a metal-containing film treatment process, such as etching, cleaning, or polishing of the metal-containing film. For a description of the metal-containing film, reference is made to the description herein.

Alternatively, the composition may also be used as an etching by-product remover, a post-etch process by-product remover, an ashing process by-product remover, a cleaning composition, a photoresist (PR) remover, an etching composition for a packaging process, a cleaning agent for a packaging process, a wafer adhesive material remover, an etchant, a post-etch residue stripper, an ash residue cleaner, a PR residue stripper, a CMP cleaner, or a post-CMP cleaner.

### Method of Treating a Metal-Containing Film

Using the composition as described above, a metal-containing film including a first region and a second region, wherein the material included in the first region is different from the material included in the second region, may be effectively treated. For a description of each of the metal-containing film, the first region and the second region, reference is made to the description herein.

According to at least one example embodiment, the first region and the second region may independently include titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), and/or a combination thereof.

According to at least one example embodiment, the first region may include titanium (Ti), indium (In), aluminum (Al), lanthanum (La), scandium (Sc), gallium (Ga), and/or a combination thereof, and the second region may include tungsten (W), molybdenum (Mo), ruthenium (Ru), and/or a combination thereof.

According to at least one example embodiment, the first region may include a metal nitride, a metal oxynitride, and/or a combination thereof, and the second region may include a conductive metal.

According to at least one example embodiment, the first region may include a titanium nitride, a titanium oxynitride, and/or a combination thereof, and each of the titanium nitride and the titanium oxynitride may optionally further include indium (In), aluminum (Al), lanthanum (La), scandium (Sc), gallium (Ga), silicon (Si), and/or a combination thereof.

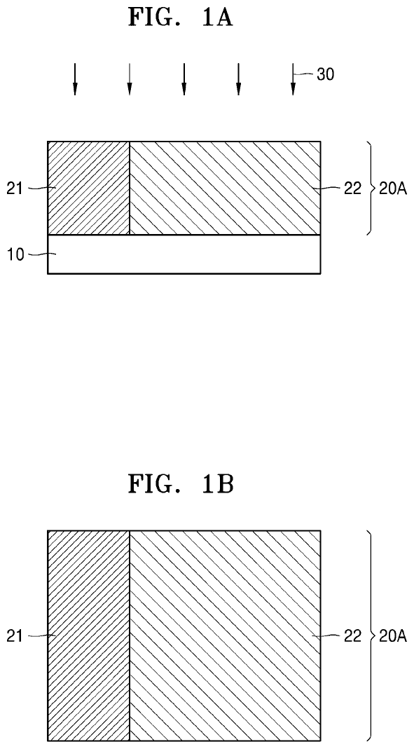

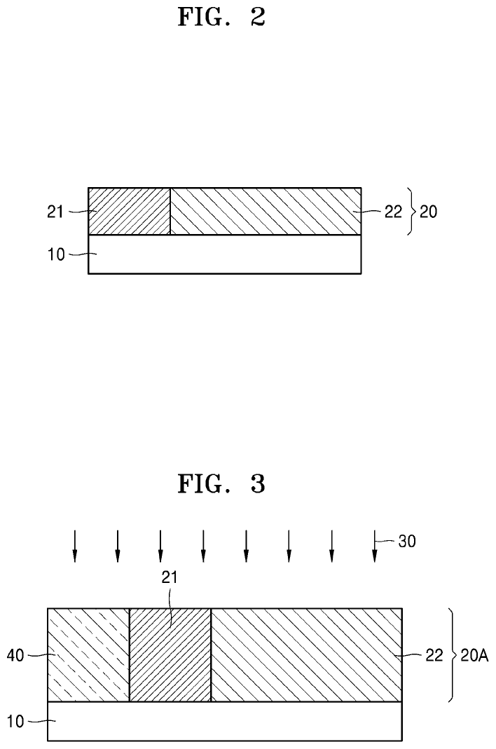

FIGS. 1A and 2 are views schematically illustrating at least one example embodiment of a metal-containing film treatment method.

Referring to FIG. 1A, a substrate 10 having a metal-containing film 20A is provided. Although not shown in FIG. 1A, various circuit elements or the like may optionally be additionally disposed between the substrate 10 and the metal-containing film 20A.

The metal-containing film 20A may include a first region 21 and a second region 22. The first region 21 and the second region 22 may be disposed apart from each other, or may be disposed at least partially in contact with each other, and the metal-containing film 20A may have various patterns. The metal-containing film 20A, including the first region 21 and the second region 22, may come into contact with composition 30, whereby a portion of the metal-containing film 20A may be removed. For example, during an etching, cleaning and/or polishing process of the metal-containing film 20A, the metal-containing film 20A may come into contact with the composition 30. The composition 30 includes an oxidizing agent, phosphoric acid, an organic acid and an etching controller as described in the specification, and for a detailed description thereof, reference is made to the description herein.

An etch rate ratio, which is obtained by dividing a first etch rate at which the composition 30 etches the first region 21 by a second etch rate at which the composition 30 etches the second region 22, may be 0.009 or greater. For example, the etch rate ratio, which is obtained by dividing the first etch rate at which the composition 30 etches the first region 21 by the second etch rate at which the composition 30 etches the second region 22, may be about 0.009 to about 1.0, about 0.01 to about 1.0, about 0.011 to about 1.0, about 0.009 to about 0.5, about 0.01 to about 0.5, about 0.011 to about 0.5, about 0.009 to about 0.2, about 0.01 to about 0.2, about 0.011 to about 0.2, about 0.009 to about 0.15, about 0.01 to about 0.15, about 0.011 to about 0.15, about 0.009 to about 0.12, about 0.01 to about 0.12, or about 0.011 to about 0.12. As another example, the etch rate ratio, which is obtained by dividing the first etch rate at which the composition 30 etches the first region 21 by the second etch rate at which the composition 30 etches the second region 22, may be about 0.05 to about 1.0, about 0.07 to about 1.0, about 0.085 to about 1.0, about 0.05 to about 0.5, about 0.07 to about 0.5, about 0.085 to about 0.5, about 0.05 to about 0.2, about 0.07 to about 0.2, about 0.085 to about 0.2, about 0.05 to about 0.15, about 0.07 to about 0.15, about 0.085 to about 0.15, about 0.05 to about 0.12, about 0.07 to about 0.12, or about 0.085 to about 0.12.

FIG. 1B is a view schematically illustrating a surface of a metal-containing film 20A that may be in contact with a composition 30. An etching area ratio, which is obtained by dividing a first area of a first region 21 exposed for contact with the composition 30 by a second area of a second region 22 exposed for contact with the composition 30, may be about 0.05 to about 1.0, about 0.05 to about 0.9, about 0.05 to about 0.7, about 0.05 to about 0.5, about 0.05 to about 0.4, about 0.05 to about 0.3, or about 0.05 to about 0.2.

When the metal-containing film 20A comes into contact with the composition 30, the relatively high reactivity of metals included in the metal-containing film 20A (for example, a metal such as molybdenum contained in the second region 22) may be controlled through the interaction of the oxidizing agent, phosphoric acid, organic acid, and etching controller included in composition 30. As a result, the etch rate of the region containing the relatively highly reactive metal (for example, the etch rate of second region 22) among the first region 21 and the second region 22 may be properly controlled. Accordingly, portions of both the first region 21 and the second region 22 may be etched such that a metal-containing film pattern 20 having a substantially planar surface (for example, having little or no step height difference between the first region 21 and the second region 22), as illustrated in FIG. 2, may be formed. Furthermore, after the contact process with the composition 30, various by-products derived from the metal-containing film 20A (for example, metal oxides derived from the metal-containing film 20A such as molybdenum oxide) may be substantially absent from the surface of the metal-containing film pattern 20. For example, the presence or absence of the by-products may be verified through analyses such as transmission electron microscopy (TEM), scanning electron microscopy (SEM) or the like.

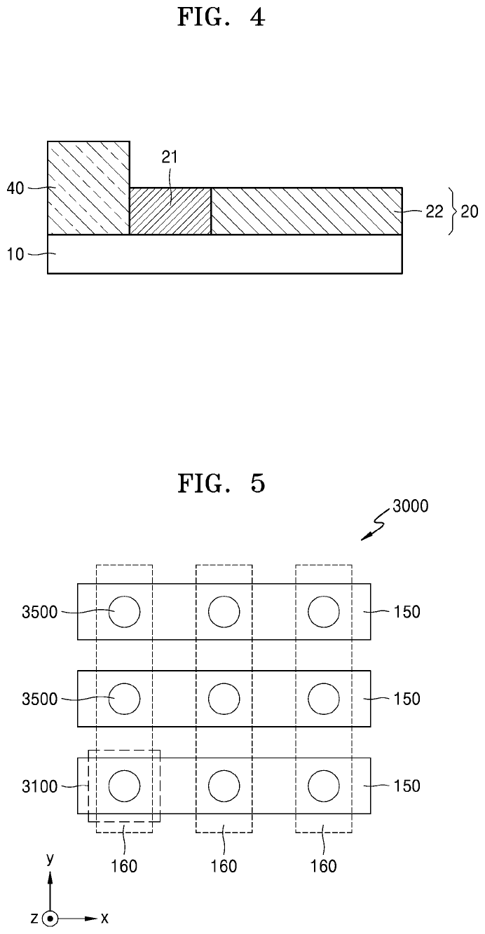

FIGS. 3 and 4 are views schematically illustrating some example embodiments of the metal-containing film treatment method.

Referring to FIG. 3, a substrate 10 is provided in which, in addition to the metal-containing film 20A, an additional material 40 is provided adjacent to the metal-containing film 20A. For a description of each of the metal-containing film 20A and the substrate 10 of FIG. 3, reference is made to FIG. 1A.

The additional material 40 in FIG. 3 may be disposed spaced apart from the metal-containing film 20A or may be at least partially in contact with it. As used herein, the term “the additional material 40” refers to a material other than the metal-containing film 20A, which is disposed adjacent to metal-containing film 20A and is located in a region that may be affected by the composition 30 during the treatment of metal-containing film 20A using the composition 30.

The additional material 40 may include at least one of an insulating material and a semiconductor material. The insulating material and semiconductor material may include various known materials. The additional material 40 may have etch selectivity compared to the metal containing film 20A (with respect to the composition 30).

The insulating material may include various oxides, nitrides, oxynitrides, high-dielectric materials, or combinations thereof. The high-dielectric materials may be a material with a dielectric constant (k) greater than silicon dioxide; and may also be referred to as a high-k material. For example, the insulating material may include silicon oxide, silicon nitride, silicon oxynitride, aluminum oxide, hafnium oxide, hafnium oxynitride, zirconium oxide, or a combination thereof. The hafnium oxide and hafnium oxynitride may optionally further include Si, Ta, Ti, Zr and/or a combination thereof. As another example, the insulating material may include tetraethyl orthosilicate (TEOS), hydrogen silsesquioxane (HSQ), methyl silsesquioxane (MSQ), or the like.

The semiconductor material may be, for example, a material included in a channel or the like, and may include: a Group IV semiconductor material such as silicon, germanium (Ge), silicon-germanium (SiGe), and silicon carbide (SiC); a Group III-V semiconductor material such as gallium arsenide (GaAs), indium arsenide (InAs), and indium phosphide (InP); as well as an oxide semiconductor, a nitride semiconductor, and an oxynitride semiconductors. The oxide semiconductor may include, for example, Indium Gallium Zinc Oxide (IGZO), Indium Tin Zinc Oxide (ITZO), Indium Tin Gallium Oxide (ITGO), Indium Tungsten Oxide (IWO), Indium Tin Oxide (ITO), ZnO, Cu₂O, and/or a combination thereof.

As shown in FIG. 3, the metal-containing film 20A including the first region 21 and the second region 22, and the additional material 40, may be brought into contact with the composition 30, and a portion of the metal-containing film 20A may be removed. For example, during an etching, cleaning, and/or polishing process of the metal-containing film 20A including the first region 21 and the second region 22, the metal-containing film 20A may be brought into contact with the composition 30. The composition 30 includes an oxidizing agent, phosphoric acid, an organic acid and an etching controller as described in this specification, and for a detailed description thereof, reference is made to the description herein.

When the metal-containing film 20A comes into contact with the composition 30, a portion of the metal-containing film 20A may be removed. Specifically, upon contact between the metal-containing film 20A and the composition 30, due to the interaction among the oxidizing agent, phosphoric acid, organic acid, and etching controller included in composition 30, the high reactivity of the metal included in the metal-containing film 20A (for example, a metal such as molybdenum included in second region 22) may be controlled. As a result, the etch rate of the region including a relatively highly reactive metal among the first region 21 and the second region 22 (for example, the etch rate of the second region 22) may be appropriately controlled, such that portions of both the first region 21 and the second region 22 are etched. Accordingly, as illustrated in FIG. 4, a metal-containing film pattern 20 having a substantially planar surface (for example, with little or no step height difference between the first region 21 and the second region 22) may be formed. Furthermore, after the contact process with the composition 30, various by-products derived from the metal-containing film 20A (for example, metal oxides derived from the metal-containing film 20A such as molybdenum oxide derived from the metal-containing film 20A) may remain substantially absent on the surface of the metal-containing film pattern 20. In addition, for example, the additional material 40, which includes at least one of an insulating material and a semiconductor material, may remain substantially undamaged by the composition 30.

### Method of Manufacturing an Electronic Device

Using the composition described above, an electronic device may be manufactured. Accordingly, a method of manufacturing an electronic device using the composition may be provided.

According to an aspect of the disclosure, a method of manufacturing an electronic device including a transistor is provided, wherein the transistor includes, a channel; a source and a drain spaced apart from each other and electrically connected to the channel; a gate electrode; and a gate insulating film disposed between the gate electrode and the channel, wherein the gate electrode is provided by: providing a barrier layer including a metal nitride, a metal oxynitride, or a combination thereof; providing a conductive layer including a conductive metal; and forming the gate electrode by bringing the barrier layer and the conductive layer into contact with the composition to etch a portion of the barrier layer and a portion of the conductive layer.

The channel may include, for example, a semiconductor material. For example, the channel may include: a Group IV semiconductor material such as silicon, germanium (Ge), silicon-germanium (SiGe), and silicon carbide (SiC); a Group III-V semiconductor material such as gallium arsenide (GaAs), indium arsenide (InAs), and indium phosphide (InP); an oxide semiconductor, a nitride semiconductor, and an oxynitride semiconductors. The oxide semiconductor may include, for example, Indium Gallium Zinc Oxide (IGZO), Indium Tin Zinc Oxide (ITZO), Indium Tin Gallium Oxide (ITGO), Indium Tungsten Oxide (IWO), Indium Tin Oxide (ITO), ZnO, Cu₂O, and/or a combination thereof. The semiconductor material may be an elemental semiconductor and/or a compound semiconductor. The semiconductor material may include an impurity as a dopant.

The gate insulating film may include an insulating material selected to electrically insulate the gate electrode and the channel. For example, the gate insulating film may include various oxides, nitrides, oxynitrides, high-k materials, or a combination thereof. For example, the gate insulating film may include silicon oxide, silicon nitride, silicon oxynitride, aluminum oxide, hafnium oxide, hafnium oxynitride, zirconium oxide, and/or a combination thereof. The hafnium oxide and hafnium oxynitride may optionally further include Si, Ta, Ti, Zr and/or a combination thereof.

The gate electrode may include a barrier layer and a conductive layer. The barrier layer may be disposed, for example, between the gate insulating film and the conductive layer.

In order to provide the gate electrode, the barrier layer and the conductive layer may be provided. For example, after forming the barrier layer, the conductive layer may be formed on the surface of the barrier layer. However, depending on the structure of the channel and/or gate electrode, various modifications are possible, such as forming the barrier layer on the surface of the conductive layer after the conductive layer is formed.

The barrier layer may be provided to protect against (e.g., prevent and/or reduce) peripheral diffusion of a conductive metal (for example, metal ion) included in the conductive layer and/or to facilitate smooth deposition of the conductive layer.

For a detailed description of each of the metal nitride and/or metal oxynitride that may be included in the barrier layer, reference may be made to the description of each of the metal nitride and/or metal oxynitride that may be included in the first region of the metal-containing film in this specification herein.

According to at least one example embodiment, the barrier layer may include a titanium nitride, a titanium oxynitride, or a combination thereof, and each of the titanium nitride and the titanium oxynitride may optionally further comprise indium (In), aluminum (Al), lanthanum (La), scandium (Sc), gallium (Ga), silicon (Si), and/or a combination thereof.

For a detailed description of the conductive metal that may be included in the conductive layer, reference may be made to the description of the conductive metal that may be included in the second region of the metal-containing film herein.

According to at least one example embodiment, the conductive layer may include tungsten (W), molybdenum (Mo), ruthenium (Ru), and/or a combination thereof.

Subsequently, the barrier layer and the conductive layer may be brought into contact with the composition described herein to etch a portion of the barrier layer and a portion of the conductive layer, thereby forming the gate electrode. More specifically, the conductive layer may be selected as the metal-containing film described above.

When the barrier layer and the conductive layer are brought into contact with the composition as described herein, the high reactivity of the conductive metal included in the conductive layer may be controlled through the interaction among the oxidizing agent, phosphoric acid, organic acid, and etching controller in the composition. As a result, the etch rate of the conductive layer may be properly controlled, allowing for etching of portions of both the barrier layer and the conductive layer. Accordingly, a gate electrode having a substantially planar surface (for example, with little or no step height difference between the barrier layer and the conductive layer) may be formed. Furthermore, after the contact process with the composition, various by-products derived from the conductive layer (for example, oxides of the conductive metal) may be substantially absent from the surface of the gate electrode. In addition, since at least one of the channel and gate insulating films disposed adjacent to the gate electrode may be substantially undamaged by the composition, and thus a relatively high-quality electronic device including a gate electrode having a precise pattern may be manufactured without (e.g., with substantially no) damage to an area adjacent to the gate electrode.

The electronic device may be a semiconductor memory device.

For example, the electronic device may include a volatile memory device, such as a dynamic random access memory (“DRAM”) device or a static random access memory (“SRAM”) device, a resistive random access memory (“ReRAM”) device, an electrically erasable programmable read-only memory (“EEPROM”) device, a flash memory (which may also be considered a subset of EEPROM) device, a ferroelectric random access memory (“FRAM”) device, a magnetoresistive random access memory (“MRAM”) device, and a nonvolatile memory device such as other semiconductor devices capable of storing information.

According to at least one example embodiment, the electronic device may be a DRAM device.

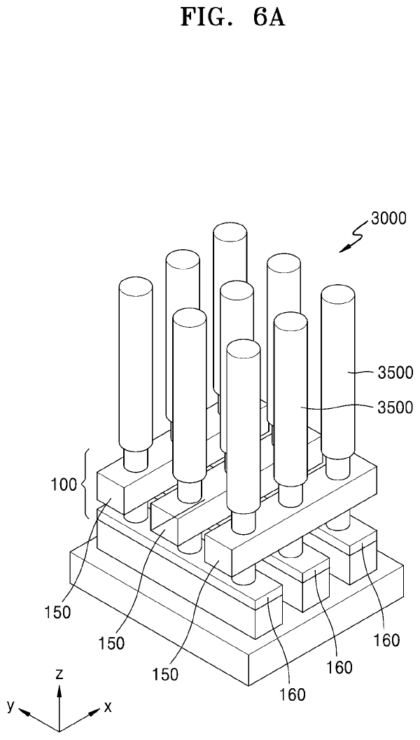

Hereinafter, the manufacturing method of the electronic device will be described in more detail with reference to FIGS. 5, 6A, 6B, 7, 8 and 9.

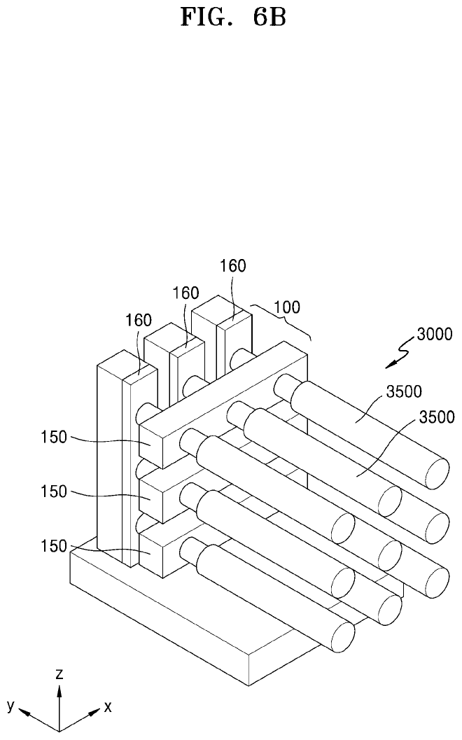

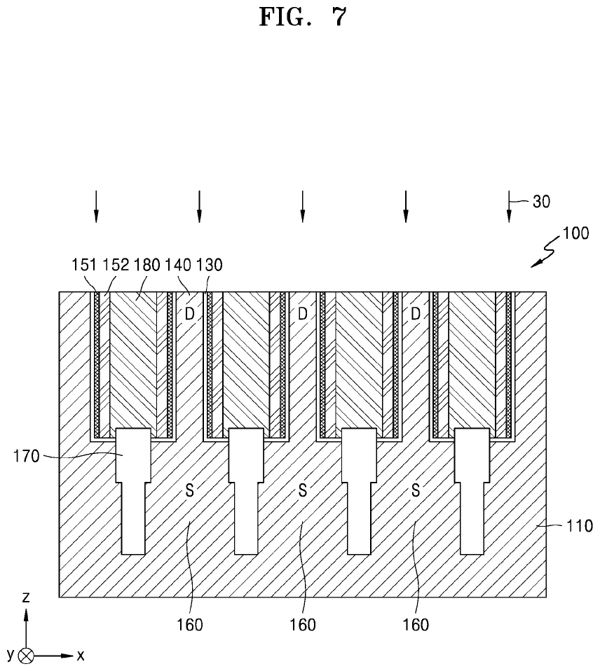

FIG. 5 is a schematic plan view of an electronic device 3000 according to at least one example embodiment, and FIG. 6A is a perspective view of the electronic device 3000 shown in FIG. 5. The electronic device 3000 of FIG. 5 may be a DRAM device.

Referring to FIGS. 5, 6A and 6B, the electronic device 3000 includes a plurality of unit elements 3100 arranged in an array form. Each unit element 3100 has a 1T1C structure consisting of one transistor and one capacitor.

The electronic device 3000 includes a transistor structure 100 and a plurality of capacitors 3500 provided to the transistor structure 100. The transistor structure 100 may be, for example, a vertical channel array transistor structure including channels arranged vertically with respect to the substrate (see FIG. 6A), or a channel array transistor structure including channels arranged and stacked horizontally with respect to the substrate (see FIG. 6B).

In the transistor structure 100, a plurality of gate electrodes (or word lines, 150) and a plurality of bit lines 160 are provided to intersect each other. Each gate electrode 150 may be provided to extend in a first direction (for example, the x-axis direction), and each bit line 160 may be provided to extend in a second direction (for example, the y-axis direction) intersecting the first direction. Transistors are arranged at points where the plurality of gate electrodes 150 and the plurality of bit lines 160 intersect.

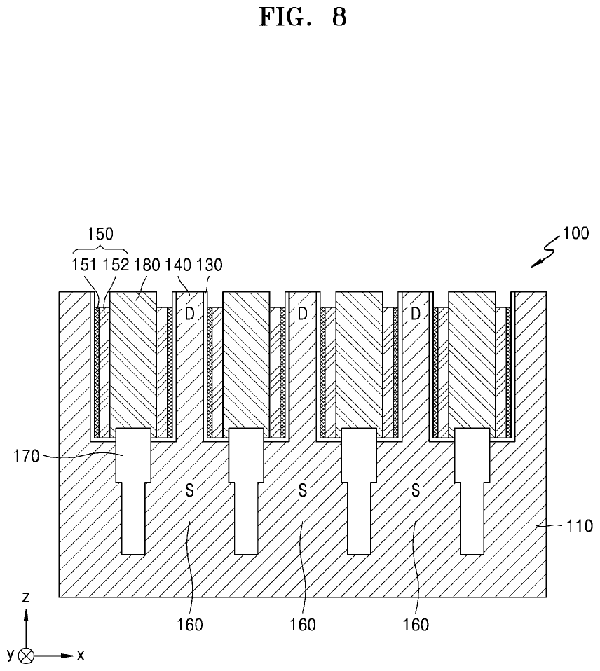

FIGS. 7 to 9 are views schematically illustrating part of the manufacturing process of the transistor structure 100 illustrated in FIG. 6A.

In FIG. 7, the transistor structure 100 includes a substrate 110 and a plurality of channels 140 arranged in an array form on the substrate 110. The plurality of channels 140 may be arranged in a two-dimensional array form on a plane (for example, xy-plane) of the substrate 110.

The substrate 110 may include a semiconductor material, for example, silicon (Si). As a specific example, the substrate 110 may be a silicon substrate doped with an n-type impurity. However, this is merely illustrative. Alternatively, the substrate 110 may include, for example, a Group IV semiconductor material such as germanium (Ge), silicon-germanium (SiGe), or silicon carbide (SiC); a Group III-V semiconductor material such as gallium arsenide (GaAs), indium arsenide (InAs), or indium phosphide (InP); or an oxide semiconductor, nitride semiconductor, oxynitride semiconductor or the like.

Each of the plurality of channels 140 may be provided to extend vertically from the substrate 110. Each channel 140 may be provided to protrude vertically from the upper surface of the substrate 110. In at least some example embodiments, the channel 140 may be formed integrally with the substrate 110 and thus may include the same semiconductor material as the substrate 110. In FIG. 7, the channels 140 are shown formed integrally with the substrate 110, but various modifications are possible, such as the channel 140 being formed separately from the substrate 110.

A source(S) and a drain (D) are provided at the bottom and top of each channel 140, respectively. The source(S) is provided to be electrically connected to the bottom of the channel 140, and the drain (D) is provided to be connected to the top of the channel 140. For example, the source(S) and drain (D) may be formed through the formation of a doped region. The capacitor 3500 illustrated in FIG. 5 may be connected to a drain (D) provided at the upper portion of the channel 140.

On the top surface of the substrate 110, sources(S) are provided in an array form corresponding to channels 140. Beneath the sources(S), a plurality of bit lines 160 are provided to extend along a second direction (for example, the y-axis direction). Each bit line 160 may electrically connect the sources(S) arranged along the second direction. The plurality of bit lines 160 may be formed within the substrate 110 and thus may include the same semiconductor material as the substrate 110. In FIG. 7, the bit lines 160 are formed using a material separate from the substrate 110; however, various modifications are possible.

A plurality of insulating materials 170 may be provided in the substrate 110 between the bit lines 160. The plurality of insulating materials 170 may be provided to extend along the second direction, in parallel with the plurality of bit lines 160, thereby separating the plurality of bit lines 160 within the substrate 110. The insulating material 170 may include, for example, silicon oxide, silicon nitride, silicon oxynitride, aluminum oxide, hafnium oxide, hafnium oxynitride, zirconium oxide, or a combination thereof.

A gate insulating film 130 is provided on the surface of the channels 140. The gate insulating film 130 may include an insulating material as described herein, for example, silicon oxide, silicon nitride, silicon oxynitride, aluminum oxide, hafnium oxide, hafnium oxynitride, zirconium oxide, or a combination thereof.

In the substrate 110 provided with the channels 140 and the gate insulating film 130 as described above, a gate electrode 150 may be provided in a trench defined at least in part by the gate insulating film 130. The gate electrode 150 may include a barrier layer 151 including a metal nitride, a metal oxynitride, or a combination thereof, and a conductive layer 152 including a conductive metal, in the trench, as illustrated in FIG. 7. For example, after forming the barrier layer 151, the conductive layer 152 may be formed on the surface of the barrier layer 151. However, depending on the structure of the channels 140 and/or gate electrode 150, various modifications are possible, such as forming the barrier layer 151 on the surface of the conductive layer 152 after the conductive layer 152 is formed. For a description of the metal nitride and/or metal oxynitride included in the barrier layer 151, and of the conductive metal included in the conductive layer 152, reference is made to the descriptions herein.

Subsequently, as illustrated in FIG. 7, an embedded insulating layer 180 is provided within a trench at least partially defined by the conductive layer 152. The embedded insulating layer 180 may serve to protect the gate electrode 150 of FIG. 8 from the penetration of oxygen and the like. After forming the embedded insulating layer 180, if necessary, a planarization process may additionally be performed so that the top surfaces of the barrier layer 151 and the conductive layer 152 are exposed.

Then, the exposed top surfaces of the barrier layer 151 and the conductive layer 152 are brought into contact with the composition 30 to etch a portion of the barrier layer 151 and a portion of the conductive layer 152, thereby forming the gate electrode 150 having the pattern shown in FIG. 8. The composition 30 in FIG. 7 includes an oxidizing agent, phosphoric acid, an organic acid, and etching controller as described in this specification, and for a detailed description thereof, reference is made to the descriptions herein.

An etch rate ratio, which is obtained by dividing a first etch rate at which the composition 30 etches the barrier layer 151 by a second etch rate at which the composition 30 etches the conductive layer 152, may be 0.009 or more. For example, the etch rate ratio, which is obtained by dividing the first etch rate at which the composition 30 etches the barrier layer 151 by the second etch rate at which the composition 30 etches the conductive layer 152, may be about 0.009 to about 1.0, about 0.01 to about 1.0, about 0.011 to about 1.0, about 0.009 to about 0.5, about 0.01 to about 0.5, about 0.011 to about 0.5, about 0.009 to about 0.2, about 0.01 to about 0.2, about 0.011 to about 0.2, about 0.009 to about 0.15, about 0.01 to about 0.15, about 0.011 to about 0.15, about 0.009 to about 0.12, about 0.01 to about 0.12, and/or about 0.011 to about 0.12. As another example, the etch rate ratio, which is obtained by dividing the first etch rate at which the composition 30 etches the barrier layer 151 by the second etch rate at which the composition 30 etches the conductive layer 152, may be about 0.05 to about 1.0, about 0.07 to about 1.0, about 0.085 to about 1.0, about 0.05 to about 0.5, about 0.07 to about 0.5, about 0.085 to about 0.5, about 0.05 to about 0.2, about 0.07 to about 0.2, about 0.085 to about 0.2, about 0.05 to about 0.15, about 0.07 to about 0.15, about 0.085 to about 0.15, about 0.05 to about 0.12, about 0.07 to about 0.12, and/or about 0.085 to about 0.12.

Meanwhile, an etching area ratio, which is obtained by dividing a first area of the barrier layer 151 exposed for contact with the composition 30 by a second area of the conductive layer 152 exposed for contact with the composition 30, may be about 0.05 to about 1.0, about 0.05 to about 0.9, about 0.05 to about 0.7, about 0.05 to about 0.5, about 0.05 to about 0.4, about 0.05 to about 0.3, and/or about 0.05 to about 0.2.

When the barrier layer 151 and the conductive layer 152 come into contact with the composition 30, the higher reactivity of the conductive metal included in the conductive layer 152 may be controlled (e.g., compensated for) through the interaction among the oxidizing agent, phosphoric acid, organic acid, and etching controller included in the composition 30. As a result, the etch rate of the conductive layer 152 may be appropriately controlled, and portions of both the barrier layer 151 and the conductive layer 152 may be etched. Accordingly, as illustrated in FIG. 8, a gate electrode 150 having a substantially planar top surface (for example, with little or no step height difference between the barrier layer 151 and the conductive layer 152) may be formed.

Furthermore, after the contact process with the composition 30, various by-products derived from the conductive layer 152 (for example, oxides of the conductive metal) may be substantially absent from the surface of the gate electrode 150. In addition, the channel 140, the gate insulating film 130, and the embedded insulating layer 180 arranged adjacent to the gate electrode 150 may be substantially undamaged by the composition 30, so that a relatively high-quality electronic device 3000 including a gate electrode 150 having a precise pattern may be manufactured without damage to an area adjacent to the gate electrode 150, for example, the channel 140, the gate insulating film 130, and the embedded insulating layer 180.

In FIG. 8, the plurality of gate electrodes 150 on the substrate 110 may be arranged to extend along a first direction (for example, the x-axis direction). The first direction may be a direction intersecting with the second direction described above. For example, the first direction may be a direction perpendicular to the second direction. However, it is not necessarily limited thereto.

Each gate electrode 150 is provided to correspond to the channels 140 arranged along the first direction. Specifically, each gate electrode 150 may be provided to surround the channels 140 arranged along the first direction. These gate electrodes 150 may function as word lines.

The plurality of gate electrodes 150 may be provided to intersect with a plurality of insulating materials 170 provided thereunder. The top surface of the insulating materials 170 may be provided so as to be adjacent to the bottom surface of the gate electrodes 150. The top of the insulating materials 170 may be provided to protrude from the bottom of the gate electrodes 150, but is not limited thereto.

Subsequently, as shown in FIG. 9, an insulating layer 190 may be additionally provided on the surface of the etched barrier layer 151 and the surface of the etched conductive layer 152. The insulating layer 190 may serve to further insulate the gate electrode 150 from the channel 140, and may include, for example, an insulating material as described herein.

### Method of Manufacturing an Electronic Apparatus

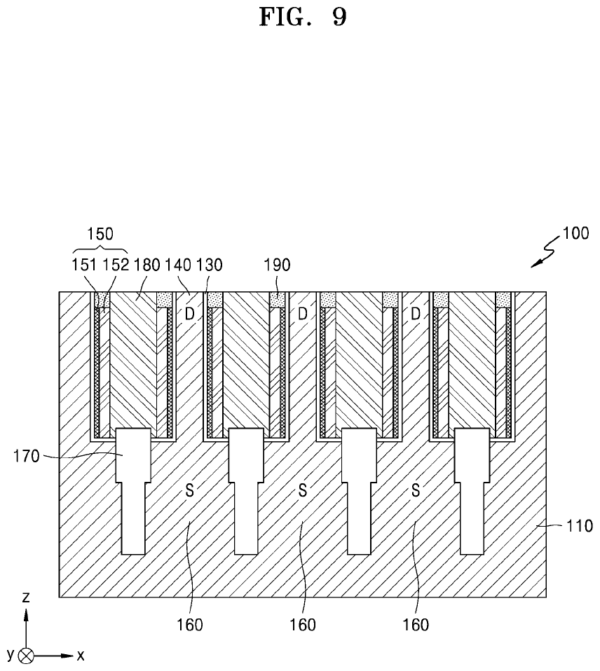

Referring to FIG. 10, at least one example embodiment of a method of manufacturing an electronic apparatus may include: preparing a substrate on which is provided a metal-containing film (S100); bringing the metal-containing film into contact with a composition as described herein; and manufacturing the electronic element using subsequent processes (120). The subsequent processes may include various known processes for manufacturing electronic elements, such as a capacitor formation process.

### Example 1 and Comparative Examples C1 to C4

Compositions of Example 1 and Comparative Examples C1 to C4 were prepared by mixing materials weighed according to the contents listed in Table 1, including an oxidizing agent, inorganic acid, organic acid, and etching controller. The remainder of each composition corresponds to water (deionized water). The numbers in parentheses in Table 1 represent the weight of the corresponding substance per 100 wt % of the composition, and the unit is wt %.

### Evaluation Example 1

The composition of Example 1 was placed in three separate beakers and heated to 60° C. Then, test samples of a titanium nitride-containing film, a molybdenum film, and a silicon oxide film (each having a size of 1 centimeters (cm)×1 cm) were immersed in the respective beakers for 1 minute. The thicknesses of the titanium nitride-containing film, molybdenum film, and silicon oxide film were measured using an ellipsometer (M-2000, J. A. Woollam), a four-point probe, and X-ray fluorescence spectroscopy (XRF), respectively. Based on these measurements, the following were evaluated: the etch rate of the titanium nitride-containing film by the composition of Example 1 (also referred to as “etch rate of the titanium nitride-containing film”); the etch rate of the molybdenum film by the composition of Example 1 (also referred to as “etch rate of the molybdenum film”); the etch rate ratio R, defined as the etch rate of the titanium nitride-containing film divided by that of the molybdenum film; and the etch rate of the silicon oxide film by the composition of Example 1 (also referred to as “etch rate of the silicon oxide film”). The results of these evaluations, along with the pH of the composition of Example 1, are summarized in Table 1. The unit of each etch rate is “Å/min”. In addition, the surface of the molybdenum film obtained after immersion in the composition of Example 1 was analyzed using Transmission Electron Microscope (TEM) and Energy-dispersive X-ray Spectroscopy (TEM-EDS) to evaluate the presence of molybdenum oxide residues. The results are also summarized in Table 1.

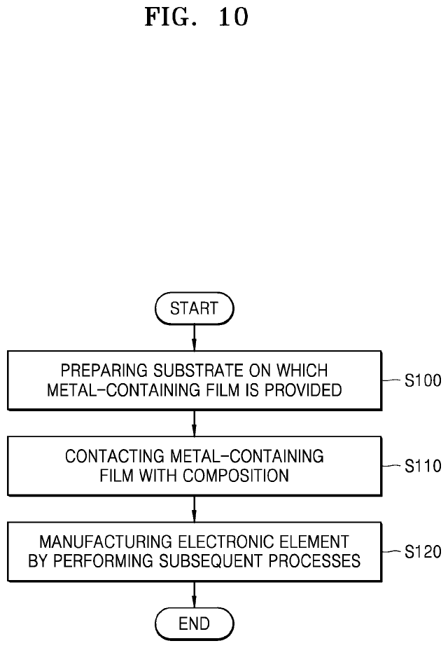

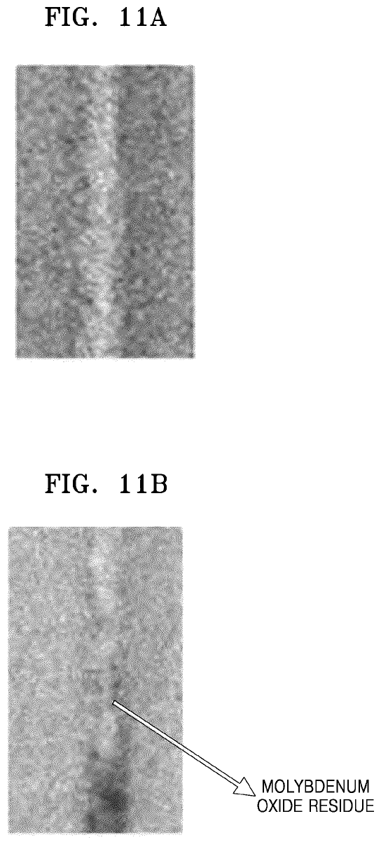

The same tests were repeated using each of the compositions of Comparative Examples C1 to C4, and the results are also summarized in Table 1. In Comparative Examples C3 and C4, the molybdenum films were completely dissolved during immersion, making it impossible to evaluate the molybdenum etch rates and the etch rate ratio R for C3 and C4. The surface image of the molybdenum film obtained after immersion in the composition of Example 1 is shown in FIG. 11A, and the surface image of the molybdenum film obtained after immersion in the composition of Comparative Example C1 is shown in FIG. 11B.

TABLE 1

| | | | | | | | Etch | | | | |
|---|---|---|---|---|---|---|---|---|---|---|---|
| | | | | | | | Rate of | | | Etch | |
| | | | | | | | Titanium | Etch | | Rate of | Observation |
| | | | | | | | Nitride- | Rate of | | Silicon | of |
| | | | | | | | Containing | Molybdenum | | Oxide | Molybdenum |
| | Oxidizing | | Inorganic | Organic | Etching | | Film | Film | | Film | Oxide |
| | Agent | | acid | acid | Controller | pH | (Å/min) | (Å/min) | R | (Å/min) | Residue |
| Example | H₂O₂ | Iodic | Phos | Acetic | A29 | −0.4 | 2.5 | 190 | 0.013 | <1 | X |
| 1 | (0.5) | acid | phoric | acid | (1) | | | | | | |
| | | (0.02) | acid | (10) | | | | | | | |
| | | | (60) | | | | | | | | |
| Comparative | H₂O₂ | — | Phosphoric | Acetic | A29 | −0.3 | 2.1 | 185 | 0.011 | <1 | O |
| Example | (0.5) | | acid | acid | (1) | | | | | | |
| C1 | | | (60) | (10) | | | | | | | |
| Comparative | — | Iodic | Phosphoric | Acetic | A32 | −0.4 | 0.5 | 64 | 0.008 | <1 | X |
| Example | | acid | acid | acid | (1) | | | | | | |
| C2 | | (0.02) | (60) | (10) | | | | | | | |
| Comparative | — | Iodic | Phos | Acetic | A31 | −0.4 | 1.8 | N/A | N/A | <1 | X |
| Example | | acid | phoric | acid | (1) | | | | | | |
| C3 | | (1) | acid | (10) | | | | | | | |
| | | | (60) | | | | | | | | |
| Comparative | H₂O₂ | Iodic | Phos | Acetic | A29 | 2.5 | 0.4 | N/A | N/A | <1 | X |
| Example | (0.5) | acid | phoric | acid | (1) | | | | | | |
| C4 | | (0.02) | acid | (10) | | | | | | | |
| | | | (5) | | | | | | | | |

X: Molybdenum oxide not observed
O: Molybdenum oxide observed 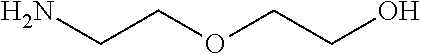
A29 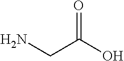
A32 (Glycine) 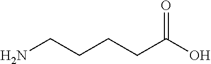
A31 (5-Aminovaleric acid)

From Table 1, and FIGS. 11A and 11B,
i) The composition of Comparative Example C1 may generate by-products such as molybdenum oxide after contact with the molybdenum film,
ii) In the composition of Comparative Example C2, the etch rate of the molybdenum film is much greater than that of the titanium nitride-containing film. Therefore, when simultaneously etching both films, excessive etching of the molybdenum film is expected. Moreover, both the titanium nitride-containing film etch rate and the molybdenum film etch rate are lower than those of Example 1, suggesting that the etching efficiency may be poor when using the composition of C2,
iii) In Comparative Examples C3 and C4, the etch rate of the molybdenum film is so greater than that of the titanium nitride-containing film that the molybdenum films were dissolved during immersion. Therefore, when simultaneously etching both films, excessive etching of the molybdenum film is expected, and
iv) In contrast, the composition of Example 1 appropriately controls the etch rate of the molybdenum film relative to that of the titanium nitride-containing film, without damaging the adjacent silicon oxide film or generating by-products such as molybdenum oxide. This confirms that excessive etching of the molybdenum film during simultaneous etching may be substantially prevented.

### Examples 11 to 13

Compositions for Examples 11 to 13 were each prepared by mixing materials weighed according to the contents listed in Table 2, including an oxidizing agent, inorganic acid, organic acid, and etching controller. The remainder of each composition corresponds to water (deionized water). The numbers in parentheses in Table 2 indicate the weight of each component per 100 wt % of the composition, with the unit being wt %. The weight-average molecular weight of the polymer P1 used as the etching controller in Example 13 was 1600 g/mol, and the content of polymer P1 listed in Table 5 represents the solid content of polymer P1.

### Evaluation Example 2

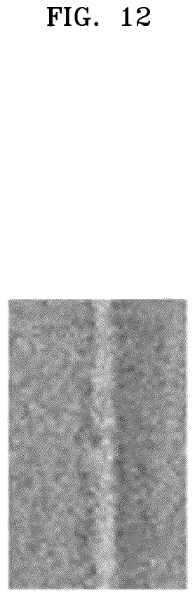

For the compositions of Examples 11 to 13, the pH, etch rate of the titanium nitride-containing film, etch rate of the molybdenum film, etch rate ratio R (defined as the etch rate of the titanium nitride-containing film divided by that of the molybdenum film), etch rate of the silicon oxide film, and presence of molybdenum oxide residues were evaluated using the same method as described in Evaluation Example 1. The results are summarized in Table 2. The surface image of the molybdenum film obtained after immersion in the composition of Example 11 is shown in FIG. 12.

TABLE 2

| | | | | | | | Etch | | | | |
|---|---|---|---|---|---|---|---|---|---|---|---|
| | | | | | | | Rate of | | | Etch | |
| | | | | | | | Titanium | Etch | | Rate of | |
| | | | | | | | Nitride- | Rate of | | Silicon | Observation |
| | | | | | | | Containing | Molybdenum | | Oxide | of |
| | Oxidizing | | Inorganic | Organic | Etching | | Film | Film | | Film | Molybdenum |
| | Agent | | Acid | Acid | Controller | pH | (Å/min) | (Å/min) | R | (Å/min) | Oxide |
| Example | H₂O₂ | Iodic | Phosphoric | Acetic | A1 | −0.4 | 1.8 | 15.3 | 0.12 | <1 | X |
| 11 | (0.5) | acid | acid | acid | (1) | | | | | | |
| | | (0.02) | (60) | (10) | | | | | | | |
| Example | H₂O₂ | Iodic | Phosphoric | Acetic | A2 | −0.4 | 2.0 | 18.7 | 0.11 | <1 | X |
| 12 | (0.5) | Acid | Acid | Acid | (1) | | | | | | |
| | | (0.02) | (60) | (10) | | | | | | | |
| Example | H₂O₂ | Iodi | Phosphoric | Acetic | P1 | −0.4 | 1.1 | 13.0 | 0.085 | <1 | X |
| 13 | (0.5) | Acid | Acid | Acid | (1) | | | | | | |
| | | (0.02) | (60) | (10) | | | | | | | |

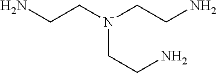

A1 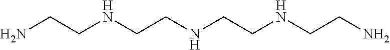 [SMILES: NCCNCCNCCNCCN]
A2 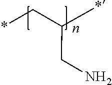
P1

Based on Table 2 and FIG. 12, it may be confirmed that the compositions of Examples 11, 12, and 13 appropriately control the etch rate of the molybdenum film relative to that of the titanium nitride-containing film, without damaging the adjacent silicon oxide film or generating by-products such as molybdenum oxide. As a result, excessive etching of the molybdenum film during the simultaneous etching of the titanium nitride-containing film and the molybdenum film may be substantially prevented.

The composition allows for easy control of the etch rate across various metal-containing films and may be effectively used in a range of processing for such films, including etching, cleaning, and polishing. Accordingly, by treating a metal-containing film with the composition, relatively high-quality electronic devices and/or electronic apparatuses may be manufactured.

It should be understood that embodiments described herein should be considered in a descriptive sense only and not for purposes of limitation. Descriptions of features or aspects within each embodiment should typically be considered as available for other similar features or aspects in some example embodiments. While one or more embodiments have been described with reference to the figures, it will be understood by those of ordinary skill in the art that various changes in form and details may be made therein without departing from the spirit and scope as defined by the following claims.

What is claimed is:

1. A method of treating a metal-containing film, comprising:
preparing a substrate including the metal-containing film, the metal-containing film including a first region and a second region, the first region including a material different from a material of the second region; and
contacting the metal-containing film with a composition;
wherein the first region and the second region independently comprise titanium (Ti), indium (In), aluminum (Al), lanthanum (La), scandium (Sc), gallium (Ga), tungsten (W), molybdenum (Mo), ruthenium (Ru), zinc (Zn), hafnium (Hf), cobalt (Co), copper (Cu), or a combination thereof,
the composition comprises an oxidizing agent, phosphoric acid, an organic acid, and an etching controller,
the oxidizing agent comprises hydrogen peroxide and an iodine-containing compound,
the etching controller comprises a nitrogen-containing compound, and
the composition has a pH of less than 1.

2. The method of claim 1,
wherein the first region comprises titanium (Ti), indium (In), aluminum (Al), lanthanum (La), scandium (Sc), gallium (Ga), or a combination thereof, and
the second region comprises tungsten (W), molybdenum (Mo), ruthenium (Ru), or a combination thereof.

3. The method of claim 1,
wherein the first region comprises a metal nitride, a metal oxynitride, or a combination thereof, and
the second region comprises a conductive metal.

4. The method of claim 1,
wherein the first region comprises a titanium nitride, a titanium oxynitride, or a combination thereof, and
optionally further comprises indium (In), aluminum (Al), lanthanum (La), scandium (Sc), gallium (Ga), silicon (Si), or a combination thereof.

5. The method of claim 1, wherein an etching area ratio of the first region to the second region is in a range of about 0.05 to about 1.0 when in exposed to the composition.

6. The method of claim 1, wherein a content of the hydrogen peroxide in the composition is about 0.01 wt % to about 10 wt % based on 100 wt % of the composition, and a content of the iodine-containing compound in the composition is about 0.001 wt % to about 5 wt % based on 100 wt % of the composition.

7. The method of claim 1, wherein a content of the phosphoric acid in the composition is about 10 wt % to about 85 wt % based on 100 wt % of the composition.

8. The method of claim 1, wherein the nitrogen-containing compound comprises an amine-containing alcohol, an amine-containing acid, a polyalkylene polyamine, a cyclic group-containing amine, a polymer having a nitrogen-containing repeating unit, or a combination thereof.

9. The method of claim 1, wherein the composition has a pH of about −3.0 to about 0.9.

10. A method of manufacturing an electronic device including a transistor, the transistor comprising a channel, a source and a drain spaced apart from each other and electrically connected to the channel, a gate electrode, and a gate insulating film between the gate electrode and the channel, the method comprising:
providing a barrier layer, the barrier layer comprising a metal nitride, a metal oxynitride, or a combination thereof;
providing a conductive layer including a conductive metal; and
forming the gate electrode by etching a portion of the barrier layer and a portion of the conductive layer using a composition, the composition comprising an oxidizing agent, phosphoric acid, an organic acid, and an etching controller,
wherein the oxidizing agent comprises hydrogen peroxide and an iodine-containing compound,
the etching controller comprises a nitrogen-containing compound, and
the composition has a pH of less than 1.

11. The method of claim 10,
wherein the barrier layer comprises a titanium nitride, a titanium oxynitride, or a combination thereof,
optionally further comprises indium (In), aluminum (Al), lanthanum (La), scandium (Sc), gallium (Ga), silicon (Si), and/or a combination thereof, and
the conductive layer comprises tungsten (W), molybdenum (Mo), ruthenium (Ru), or a combination thereof.

12. The method of claim 10, further comprising: providing an insulating layer on a surface of the barrier layer and a surface of the conductive layer after the etching of the portion of the barrier layer and the portion of the conductive layer.

13. A composition comprising:
an oxidizing agent;
phosphoric acid;
an organic acid; and
an etching controller,
wherein the oxidizing agent comprises hydrogen peroxide and an iodine-containing compound,
the etching controller comprises a nitrogen-containing compound, and
the composition has a pH of less than 1.

14. The composition of claim 13, wherein a content of the oxidizing agent is in a range of about 0.001 wt % to about 10 wt % based on 100 wt % of the composition.

15. The composition of claim 13, wherein a content of the hydrogen peroxide in the composition is about 0.01 wt % to about 10 wt % based on 100 wt % of the composition, and a content of the iodine-containing compound in the composition is about 0.001 wt % to about 5 wt % based on 100 wt % of the composition.

16. The composition of claim 13, wherein a content of the phosphoric acid is in a range of about 10 wt % to about 85 wt % based on 100 wt % of the composition.

17. The composition of claim 13, wherein the organic acid comprises a monocarboxylic acid, a dicarboxylic acid, a tricarboxylic acid, or a combination thereof.

18. The composition of claim 13, wherein the nitrogen-containing compound comprises an amine-containing alcohol, an amine-containing acid, a polyalkylene polyamine, a cyclic group-containing amine, a polymer having a nitrogen-containing repeating unit, or a combination thereof.

19. The composition of claim 13, wherein a content of the etching controller is in a range of about 0.01 wt % to about 5 wt % based on 100 wt % of the composition.

20. The composition of claim 13, wherein the composition has a pH of about −3.0 to about 0.9.
